(19) United States
(12) Patent Application Publication
(10) Pub. No.: US 2009/0246486 A1
(43) Pub. Date: Oct. 1, 2009

(54) LIGHT-TRANSMITTABLE ELECTROMAGNETIC WAVE SHIELDING FILM, PROCESS FOR PRODUCING LIGHT-TRANSMITTABLE ELECTROMAGNETIC WAVE SHIELDING FILM, FILM FOR DISPLAY PANEL, OPTICAL FILTER FOR DISPLAY PANEL AND PLASMA DISPLAY PANEL

(75) Inventor: Hirotomo Sasaki, Kanagawa (JP)

Correspondence Address: SUGHRUE-265550, 2100 PENNSYLVANIA AVE. NW, WASHINGTON, DC, 20037-3213, US

(73) Assignee: FUJIFILM CORPORATION, Tokyo (JP)

(21) Appl. No.: 12/067,538

(22) PCT Filed: Sep. 22, 2006
(86) PCT No.: PCT/JP2006/319399

§ 371 Date: Mar. 20, 2008

(30) Foreign Application Priority Data
Sep. 22, 2005 (JP) 2005-275378
Sep. 22, 2005 (JP) 2005-275379

(51) Int. Cl. H05K 9/00; B32B 15/08

(52) U.S. Cl. 428/203; 427/108

(57) ABSTRACT

A light-transmittable electromagnetic wave shielding film comprising: a transparent substrate; a printed pattern containing silver as a major component; and at least one rust inhibitor, a process for producing a light-transmittable electromagnetic wave shielding film, which comprises: forming a metal silver portion and a light-transmitting portion by exposing a silver salt-containing layer provided on a transparent substrate and development-processing the exposed layer; subjecting the metal silver portion to at least one of physical development and plating treatment to form an electro-conductive metal portion where an electro-conductive metal is supported on the metal silver portion; and subjecting the electro-conductive metal portion to color change-preventing treatment with an organic mercapto compound and a light-transmittable electromagnetic wave shielding film produced by the process, and a film for display panel, an optical filter for plasma display panel and a plasma display panel comprising the light-transmittable electromagnetic wave shielding film.

### TECHNICAL FIELD

The present invention relates to a light-transmittable electromagnetic wave shielding film which can shield electromagnetic wave generated from a display screen of CRT (cathode ray tube), PDP (plasma display panel), liquid crystal, EL (electroluminescence) or FED (field emission display), a microwave oven, an electronic device and a printed wiring board and has light-transmitting properties, a process for producing a light-transmittable electromagnetic wave shielding film and a light-transmittable electromagnetic wave shielding film obtained by the process, and further relates to a film for display panel, an optical filter for display panel and a plasma display panel using the shielding film.

### BACKGROUND ART

In recent years, accompanied by the increase of use of various electric equipment and electronic application equipment, EMI (Electro-Magnetic Interference) has sharply increased. This EMI has been known to cause operation errors or troubles in electronic or electric devices. Therefore, electronic or electric devices are required to suppress intensity of released electromagnetic wave within a standard or a regulation.

In order to take measures to cope with the problem of EMI, it is necessary to shield electromagnetic wave. It is self-evident that, for such purpose, utilization of the properties of metals of not penetrating electromagnetic wave suffices. For example, there have been employed a method of making a housing of a metal or a highly electrically conductive substance, a method of inserting a metal plate between circuit substrates, and a method of covering a cable with a metal foil. With CRT or PDP, however, transparency is required upon display since it is necessary for an operator to recognize letters or the like displayed on the screen. Therefore, the above-mentioned methods which often make the display screen opaque have been inappropriate as methods for shielding electromagnetic wave.

In particular, PDP which generates larger electromagnetic wave than CRT or the like is required to have more electromagnetic wave-shielding ability. The electromagnetic wave-shielding ability can be simply represented by a surface resistance value. For example, light-transmittable electromagnetic wave-shielding materials for use in CRT are required to have a surface resistance value of about 300 Ω/sq or less, whereas light-transmittable electromagnetic wave-shielding materials for use in PDP are required to have a surface resistance value of 2.5 Ω/sq or less. With plasma television sets using PDP, the surface resistance value is required to be 1.5 Ω/sq or less, more preferably an extremely high electrical conductivity of as high as 0.1 Ω/sq or less.

Also, as to transparency level required, a transparency of about 70% or more (transmittance for total visible light) is required for use in CRT, and a transparency of about 80% or more is required for use in PDP, with much higher transparency being desired.

For the purpose of solving the above-described problem, various materials and methods have been proposed which can provide both an electromagnetic wave-shielding ability and a light-transmitting ability utilizing a metal mesh having openings. As a typical example thereof, there is an etching-processed mesh utilizing a photolithography method. The conventional etching-processed mesh utilizing the photolithography method permits such fine processing that a mesh with a high opening ratio (high transmittance) can be prepared, and has the advantage that a strong electromagnetic wave can be shielded. On the other hand, the mesh involves the problem that the production steps for the mesh are complicated and expensive, thus its improvement having been desired.

As a method for producing a metal mesh at a low cost, there has been proposed a method of printing a paste or ink containing metal particles in a lattice pattern to obtain a metal mesh.

For example, JP-A-2003-318593 discloses a method of producing an electromagnetic wave shielding member by printing a dispersion of fine particles of a conductive material such as silver employing an ink jet method, followed by heating and baking.

Also, JP-A-2004-119880 discloses a method of producing an electromagnetic wave shielding film by printing a paste containing a silver compound and heating to accelerate reduction and decomposition of the silver compound to silver metal and accelerate fusing of the metal particles to each other.

Further, as a method for producing a metal mesh at a low cost to satisfy the requirement, there has been proposed a method utilizing the principle of silver salt photography.

For example, JP-A-2004-221564 discloses a method of producing an electromagnetic wave shielding member by preparing a silver halide light-sensitive material, exposing this in a mesh pattern, development-processing it, and subjecting it to a plating treatment.

### DISCLOSURE OF THE INVENTION

In comparison with the process for producing an etching-processed mesh utilizing photolithography, the metal mesh obtained by utilizing the printing method as described above or the silver halide photographic method as described above has the advantage that it permits to produce in fewer steps and that production cost might be reduced. On the other hand, it has involved the following problem.

That is, the metal portion fails to have sufficient chemical resistance which is required for an electromagnetic wave shielding material to be utilized in display, thus having been desired to be improved.

Also, in addition to the chemical resistance of the metal portion, a non-metal portion that transmits light (light-transmitting portion) involves a drawback of color change, thus having been desired to be improved.

As a result of investigation by the inventors, it has been found that, since a dispersion of fine particles of a metal or a metal compound is printed, the metal phase in the metal mesh portion does not form a completely continuous phase and is liable to form an aggregate of metal fine particles having a large surface area. That is, the surface area of the metal portion is liable to become larger than in the case of etch-processing a metal foil, which is considered to be disadvantageous in view of chemical resistance of the metal portion.

Furthermore, the metal mesh obtained by the prior printing method, in the case that the metal is constituted of silver and has a high conductivity, shows a luster and a reflection specific to metallic silver, thus insufficient as an electromagnetic wave shield for an electronic display. For this reason, there has been desired a black material showing little reflection and not involving the aforementioned drawbacks.

The present invention has been made in consideration of such circumstances, and the object of the invention is to provide a light-transmittable electromagnetic wave shielding film which has an excellent chemical resistance such as resistance against a salt water, an excellent heat resistance, an excellent resistance to moist heat, an excellent durability, less subjection to color change in time lapse and a high electromagnetic wave-shielding ability and which produces a small light scattering and has a high light transmittance, and decrease a reflection of the metals; and a film for use in display panel, an optical filter for use in display panel and a plasma display panel for use in plasma display using the same.

Further, an object of the invention is to provide a production process which can produce inexpensively on a large scale a light-transmittable electromagnetic wave shielding film which has an excellent durability and a high electromagnetic wave-shielding ability and which produces a small light scattering and has a high light transmittance. Another object of the invention is to provide a light-transmittable electromagnetic wave shielding film obtained by the production process. A further object of the invention is to provide a film for display, an optical filter for display panel and a plasma display panel containing the light-transmittable electromagnetic wave shielding film.

As a result of intensive investigations, the present inventors have found that it is effective to suppress corrosion of the metal in view of improving chemical resistance and durability.

Further, as a result of intensive investigations in view of obtaining a light-transmittable electromagnetic wave shielding film which has an excellent durability and has both a high electromagnetic wave shielding ability and a high transparency, the present inventors have found that, in order to improve durability, it is effective to treat with an organic mercapto compound and that the above-described objects can effectively be attained by the following constitution, thus having completed the invention based on the findings.

That is, the invention is as follows.

[1] A light-transmittable electromagnetic wave shielding film comprising:

a transparent substrate;

a printed pattern containing silver as a major component; and

at least one rust inhibitor,

wherein the printed pattern containing silver as a major component comprises: an electro-conductive metal portion; and a light-transmitting portion, and

wherein the printed pattern contains silver in a content of 60% by mass or more based on a total mass of metals constituting the printed pattern.

[2] The light-transmittable electromagnetic wave shielding film as described in [1] above,

wherein the printed pattern contains silver in a content of 85% by mass or more.

[3] The light-transmittable electromagnetic wave shielding film as described in [1] or [2] above,

wherein the printed pattern contains silver and a noble metal other than silver.

[4] The light-transmittable electromagnetic wave shielding film as described in any of [1] to [3] above,

wherein the printed pattern contains silver and palladium, or silver and gold.

[5] The light-transmittable electromagnetic wave shielding film as described in any of [1] to [4] above,

wherein the at least one rust inhibitor is a 5-membered cyclic azole compound having an N—H structure.

[6] The light-transmittable electromagnetic wave shielding film as described in any of [1] to [4] above,

wherein the at least one rust inhibitor is an organic mercapto compound.

[7] The light-transmittable electromagnetic wave shielding film as described in any of [1] to [4] above,

wherein the at least one rust inhibitor is a combination of a 5-membered cyclic azole compound having an N—H structure and an organic mercapto compound.

[8] The light-transmittable electromagnetic wave shielding film as described in [6] or [7] above,

wherein the organic mercapto compound is a compound represented by formula (2):

Z-SM Formula (2)

wherein Z represents an alkyl group, an aromatic group or a hetero ring group substituted by at least one group selected from the group consisting of a hydroxyl group, —SO₃M² group, —COOM² group, an amino group and an ammonio group or by a substituent substituted by at least one member selected from the group consisting of a hydroxyl group, —SO₃M² group, —COOM² group, an amino group and an ammonio group, wherein M² represents a hydrogen atom, an alkali metal atom or an ammonium group; and

M represents a hydrogen atom, an alkali metal atom or an amidino group, which may optionally form a hydrohalogenic acid salt or a sulfonate.

[9] The light-transmittable electromagnetic wave shielding film as described in [6] or [7] above,

wherein the organic mercapto compound is at least one organic mercapto compound represented by formulae (1) and (3) to (5):

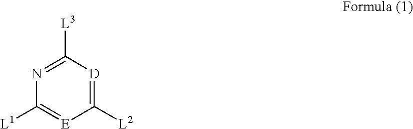

wherein -D= and -E=each independently represents —CH═ group, —C(R^{o})═ group or —N═ group;

R^{o} represents a substituent; and

L¹, L² and L³ each independently represents a hydrogen atom, a halogen atom or a substituent connected to the ring through a carbon atom, a nitrogen atom, an oxygen atom, a sulfur atom or a phosphorus atom, provided that at least one of L¹, L², L³ and R^{o} is —SM group, wherein M represents an alkali metal atom, a hydrogen atom or an ammonium group;

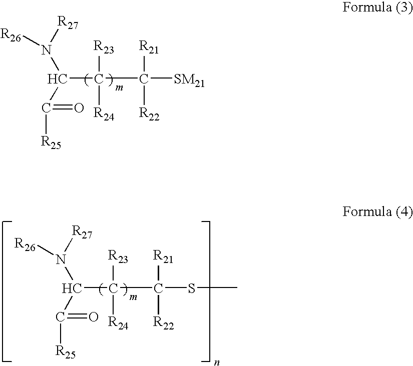

wherein R₂₁ and R₂₂ each independently represents a hydrogen atom or an alkyl group, provided that R₂₁ and R₂₂ do not represent a hydrogen atom at the same time and that the alkyl group may have a substituent;

R₂₃ and R₂₄ each independently represents a hydrogen atom or an alkyl group;

R₂₅ represents a hydroxyl group or a salt of the hydroxyl group, an amino group, an alkyl group or a phenyl group;

R₂₆ and R₂₇ each independently represents a hydrogen atom, an alkyl group, an acyl group or —COOM₂₂, provided that R₂₆ and R₂₇ do not represent a hydrogen atom at the same time;

M₂₁ represents a hydrogen atom, an alkali metal atom or an ammonium group;

M₂₂ represents a hydrogen atom, an alkyl group, an alkali metal atom, an aryl group or an aralkyl group;

m represents 0, 1 or 2; and

n represents 2;

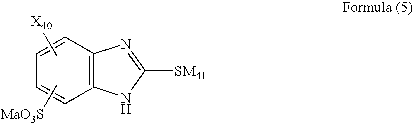

wherein X₄₀ represents a hydrogen atom, a hydroxyl group, a lower alkyl group, a lower alkoxy group, a halogen atom, a carboxyl group or a sulfo group;

M₄₁ and Ma each independently represents a hydrogen atom, an alkali metal atom or an ammonium group.

[10] The light-transmittable electromagnetic wave shielding film as described in [9] above,

wherein the organic mercapto compound is represented by formula (1).

[11] The light-transmittable electromagnetic wave shielding film as described in any of [1] to [10] above, which comprises the at least one rust inhibitor in an amount of from 0.001 to 0.04 g/m² with respect to the printed pattern.

[12] The light-transmittable electromagnetic wave shielding film as described in any of [1] to [11] above, which further comprises a functional transparent layer having one or more functions selected from among infrared ray-shielding properties, hard coat properties, anti-reflection properties, anti-glare properties, antistatic properties, stain-proof properties, UV ray-cutting properties, gas barrier properties and display panel damage-preventing properties.

[13] A film for display panel, which comprises a light-transmittable electromagnetic wave shielding film as described in any of [1] to [12] above.

[14] An optical filter for plasma display panel, which comprises a film for display panel as described in [13] above.

[15] A plasma display panel, which comprises a film for display panel as described in [13] above or an optical filter for plasma display panel as described in [14] above.

[16] A process for producing a light-transmittable electromagnetic wave shielding film, which comprises:

forming an electro-conductive metal portion and a light-transmitting portion by printing, on a transparent substrate, fine particles containing silver as a major component in a content of 60% by mass or more based on a total mass of metals; and then

subjecting the electro-conductive metal portion and the light-transmitting portion to a treatment with at least one rust inhibitor.

[17] A process for producing a light-transmittable electromagnetic wave shielding film, which comprises:

forming an electro-conductive metal portion and a light-transmitting portion by printing, on a transparent substrate, fine particles containing silver as a major component in a content of 60% by mass or more based on a total mass of metals; and then

subjecting the electro-conductive metal portion and the light-transmitting portion to a treatment with a liquid containing Pd ions; and then

subjecting the electro-conductive metal portion and the light-transmitting portion to a treatment with at least one rust inhibitor.

[18] A process for producing a light-transmittable electromagnetic wave shielding film, which comprises:

forming a metal silver portion and a light-transmitting portion by exposing a silver salt-containing layer provided on a transparent substrate and development-processing the exposed layer;

subjecting the metal silver portion to at least one of physical development and plating treatment to form an electro-conductive metal portion where an electro-conductive metal is supported on the metal silver portion; and

subjecting the electro-conductive metal portion to color change-preventing treatment with an organic mercapto compound.

[19] The process for producing a light-transmittable electromagnetic wave shielding film as described in [18] above,

wherein the organic mercapto compound is represented by formula (2):

Z-SM Formula (2)

wherein Z represents an alkyl group, an aromatic group or a hetero ring group substituted by at least one group selected from the group consisting of a hydroxyl group, —SO₃M² group, —COOM² group, an amino group and an ammonio group or by a substituent substituted by at least one member selected from the group consisting of a hydroxyl group, —SO₃M² group, —COOM² group, an amino group and an ammonio group, wherein M² represents a hydrogen atom, an alkali metal atom or an ammonium group; and

M represents a hydrogen atom, an alkali metal atom or an amidino group, which may optionally form a hydrohalogenic acid salt or a sulfonate.

[20] The process for producing a light-transmittable electromagnetic wave shielding film as described in [18] or [19] above,

wherein the organic mercapto compound is at least one organic mercapto compound represented by formulae (1) and (3) to (5):

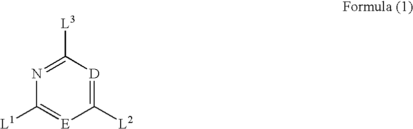

wherein -D= and -E= each independently represents —CH═ group, —C(R^{o})═ group or —N═ group;

R^{o} represents a substituent; and

L¹, L² and L³ each independently represents a hydrogen atom, a halogen atom or a substituent connected to the ring through a carbon atom, a nitrogen atom, an oxygen atom, a sulfur atom or a phosphorus atom, provided that at least one of L¹, L², L³ and R^{o} is —SM group, wherein M represents an alkali metal atom, a hydrogen atom or an ammonium group;

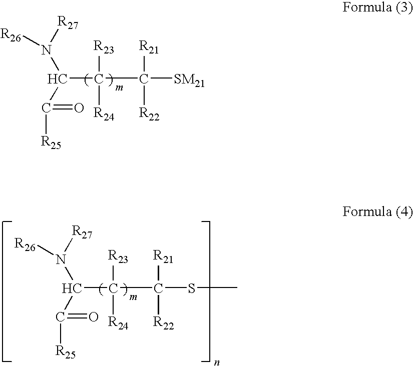

wherein R₂₁ and R₂₂ each independently represents a hydrogen atom or an alkyl group, provided that R₂₁ and R₂₂ do not represent a hydrogen atom at the same time and that the alkyl group may have a substituent;

R₂₃ and R₂₄ each independently represents a hydrogen atom or an alkyl group;

R₂₅ represents a hydroxyl group or a salt of the hydroxyl group, an amino group, an alkyl group or a phenyl group;

R₂₆ and R₂₇ each independently represents a hydrogen atom, an alkyl group, an acyl group or —COOM₂₂, provided that R₂₆ and R₂₇ do not represent a hydrogen atom at the same time;

M₂₁ represents a hydrogen atom, an alkali metal atom or an ammonium group;

M₂₂ represents a hydrogen atom, an alkyl group, an alkali metal atom, an aryl group or an aralkyl group;

m represents 0, 1 or 2; and

n represents 2;

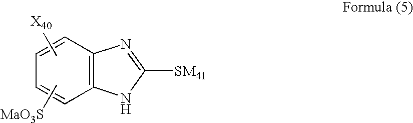

wherein X₄₀ represents a hydrogen atom, a hydroxyl group, a lower alkyl group, a lower alkoxy group, a halogen atom, a carboxyl group or a sulfo group;

M₄₁ and Ma each independently represents a hydrogen atom, an alkali metal atom or an ammonium group.

[21] A light-transmittable electromagnetic wave shielding film produced by a production process as described in any of [18] to [20] above.

[22] The light-transmittable electromagnetic wave shielding film as described in [21] above, which comprises a functional transparent layer having one or more functions selected from among infrared ray-shielding properties, hard coat properties, anti-reflection properties, anti-glare properties, antistatic properties, stain-proof properties, UV ray-cutting properties, gas barrier properties and display panel damage-preventing properties.

[23] A film for display panel, which comprises a light-transmittable electromagnetic wave shielding film as described in [21] or [22] above.

[24] An optical filter for plasma display panel, which comprises a film for display panel as described in [23] above.

[25] A plasma display panel, which comprises a film for display panel as described in [23] above or an optical filter for plasma display panel as described in [24] above.

### BEST MODE FOR CARRYING OUT THE INVENTION

The invention relating to a light-transmittable electromagnetic wave shielding film which comprises a transparent substrate having provided thereon a printed pattern containing silver as a major component and a rust inhibitor will be described in detail below. Additionally, in this specification, “-” (“to”) is used to mean that numbers before and after “-” (“to”) are included as the lower limit value and the upper limit value, respectively.

### [Transparent Substrate]

As the transparent substrate to be used in the invention, there can be used, for example, polyesters such as polyethylene terephthalate (PET) and polyethylene naphthalate; polyolefins such as polyethylene (PE), polypropylene (PP), polystyrene and EVA; vinyl series resins such as polyvinyl chloride and polyvinylidene chloride; and others such as polyether ether ketone (PEEK), polysulfone (PSE), polyether sulfone (PES), polycarbonate (PC), polyamide, polyimide, acrylic resin and triacetyl cellulose (TAC).

In the invention, the transparent plastic substrate is preferably a polyethylene terephthalate film in view of transparency, heat resistance, handling ease and price. The thickness of the transparent plastic substrate is preferably from 5 to 200 μm, more preferably from 10 to 130 μm, still more preferably from 40 to 80 μm, since a substrate with a smaller thickness would have deteriorated handling properties and a substrate with a larger thickness would have a reduced transmittance for visible light.

The substrate is required to have a high transparency because an electromagnetic wave shielding film for use in display panel is required to be transparent. The total visible light transmittance of the transparent plastic substrate for this use is preferably from 70 to 100%, more preferably from 85 to 100%, particularly preferably from 90 to 100%. In the invention, as the transparent plastic substrate, those substrates can also be used which are colored to a degree of not spoiling the effect of the invention.

The transparent plastic substrate in the invention can be used as a single layer, and also can be used as a multi-layer film comprising two or more layers.

In the invention, it is also possible to use a glass plate as the transparent substrate. There exists no limitation as to kind of the glass plate. In the case of using for an electromagnetic wave shielding film for display, however, it is preferred to use a tempered glass having a tempered layer on the surface thereof. In comparison with a non-tempered glass, the tempered glass has a high possibility of preventing breakage. Further, even when broken by any chance, a tempered glass obtained by an air-cooling method produces small broken pieces with non-sharp broken surfaces, thus being preferred in view of safety.

### [Printed Pattern]

Next, a printed pattern in the invention containing silver as a major component will be described below. The printed pattern includes an electro-conductive metal portion and a light-transmitting portion.

As a printing method, a known printing method such as a gravure printing method, an offset printing method, a typographic printing method, a screen printing method, a flexographic printing method or an inkjet printing method may be employed.

The transparent substrate may be subjected to surface treatment, or an anchor coating layer may be provided thereon. As the method of surface treatment, a treatment by coating a primer, a plasma treatment or a corona discharge treatment is effective. These treatments are conducted so that the critical surface tension of the treated transparent substrate becomes preferably 3.5×10⁻⁴ N/cm or more, more preferably 4.0×10⁻⁴ N/cm or more.

The paste or ink to be used for the printing contains a metal or a metal compound for obtaining an electro-conductive pattern by printing and, further, preferably contains a solvent, a binder and a dispersing agent for dispersing the metal or the metal compound.

As the metal, there are illustrated fine particles of silver, copper, nickel, palladium, gold, platinum or tin. In the invention, the printed pattern contains silver as a major component, and silver may be used alone or as a mixture of two or more of the above-mentioned metals including silver. However, the phrase “printed pattern containing silver as a major component” means a printed pattern containing 60% by mass or more silver based on the mass of metals constituting the pattern, preferably 85% by mass or more in consideration of conductivity and durability. In the invention, in the case of using two or more metals, it is preferred to coat one metal with the other metal. As the metal, there are illustrated, in addition to nickel, zinc, tin, cobalt and chromium, noble metals such as gold, platinum and palladium, and noble metals are particularly preferable, and silver and palladium, or silver and gold are more particularly preferable.

The coating methods include (1) a method, in preparing fine metal particles to be contained in a paste or an ink for printing, of preparing fine particles of an alloy of palladium or gold and printing such paste or ink, and (2) a method, after printing fine silver particles, of executing a treatment with a liquid containing palladium (II) ions such as Na₂PdCl₄ or an aqueous solution of chloroauric acid thereby coating silver with palladium or gold. Among these, the method (2) is particularly preferable in improving durability, such as a particularly excellent salt water resistance.

It is also possible to use a metal compound. The metal compound means a metal oxide or an organometallic compound. Compounds which easily undergo reduction or decomposition when an energy is applied thereto from outside to acquire conductivity are preferred. As the metal oxide, gold oxide or silver oxide can be used. In particular, silver oxide is preferred since it has self-reduction properties. As the organometallic compound, silver acetate or silver citrate having a comparatively small molecular mass is preferred. In the case where the paste contains a metal, the paste is preferably prepared from metal particles of nano-order size (5-60 nm), a dispersing agent and a solvent. Also, in the case where the paste contains a metal oxide, the paste is preferably prepared from metal oxide particles of nano-order size, a reducing agent necessary for reducing this metal oxide and a solvent and, in the case where the paste contains an organometallic compound, the paste is preferably prepared from an organometallic compound having a low decomposition temperature and a solvent. In particular, when a paste containing both a metal oxide of nano-order size and an organometallic compound of nano-order size is used, even fine lines can be printed. In addition, in the case of imparting electro-conductivity by applying energy from outside, reduction and decomposition of a metal oxide to a metal and fusion of metal particles to each other can be promoted under the conditions not damaging a flexible film by proper selection of the structure of the reducing agent and the organometallic compound. Hence, it becomes possible to more reduce resistance value. Additionally, in the case where the metal oxide can be reduced without the addition of a reducing agent, for example, where the metal oxide can be self-reduced by heating, addition of the reducing agent can be omitted. As to the solvent, though detailed descriptions will be given hereinafter, a proper one can be used depending upon the printing method to be employed or a method of adjusting the viscosity of the paste. A high-boiling solvent such as carbitol or propylene glycol can be used. The viscosity of the paste can properly be selected depending upon the printing method and the solvent to be employed, and is preferably from 5 mPa·s to 20000 mPa·s.

As a binder to be incorporated in the paste or ink for use in the invention, any of the resins of, for example, thermoplastic resins such as polyester resin, polyvinyl butyral resin, ethyl cellulose resin, (meth)acrylic resin, polyethylene resin, polystyrene resin and polyamide resin; and thermosetting resins such as polyester-melamine resin, melamine resin, epoxy-melamine resin, phenol resin, amino resin, polyimide resin and (meth)acrylic resins. Two or more of these resins may be copolymerized as needed, or two or more of them can be blended to use.

Specific examples of usable solvents include alcohols such as hexanol, octanol, nonanol, decanol, undecanol, dodecanol, tridecanol, tetradecanol, pentadecanol, stearyl alcohol, ceryl alcohol, cyclohexanol and terpineol; and alkyl ethers such as ethylene glycol monobutyl ether (butyl cellosolve), ethylene glycol monophenyl ether, diethylene glycol, diethylene glycol monobutyl ether (butylcarbitol), cellosolve acetate, butyl cellosolve acetate, caarbitol acetate and butylcarbitol acetate. These can properly be selected in consideration of printing adaptability and workability.

In the case of using a higher alcohol as a solvent, drying properties and flowability of the ink might be reduced. In such cases, it suffices to use butylcarbitol, butyl cellosolve, ethylcarbitol, butyl cellosolve acetate or butyl carbitol acetate which has better drying properties together with the higher alcohol. The amount of a solvent to be used is determined by the viscosity of the ink or paste. In view of the addition amount of the above-described metal powder, the amount of the solvent is usually from 100 to 500 parts by mass, preferably from 100 to 300 parts by mass, per 100 parts by mass of the binder.

As to the constitution ratio (by mass) among the metal, the binder and the solvent, 10⁻⁵ to 10² of the binder and 1 to 10⁵ of the solvent are used per 1 of the metal, preferably 10⁻³ to 10 of the binder and 10 to 10³ of the solvent are used per 1 of the metal.

The printed electro-conductive metal portion is preferably baked at an elevated temperature. The baking serves to remove the organic component and cause adhesion of fine particles of the metal to each other, thus the surface resistance value being reduced. The baking temperature is, for example, from 50 to 1000° C., preferably from 70 to 600° C., and the baking time is, for example, from 3 to 600 minutes, preferably from 10 to 30 minutes.

The light-transmittable electromagnetic wave-shielding film in the invention has an electro-conductive metal portion, thus acquiring a good electro-conductivity. Therefore, the light-transmittable electromagnetic wave-shielding film of the invention has a surface resistance value of preferably 10 Ω/sq or less, more preferably 2.5 Ω/sq or less, still more preferably 1.5 Ω/sq or less, most preferably 0.1 Ω/sq or less.

The electro-conductive metal portion in the invention is preferably disposed so as to constitute geometrical figures wherein a triangle such as an equilateral triangle, an isosceles triangle or a right triangle, a quadrilateral such as a square, a rectangle, a rhombus, a parallelogram or a trapezoid, an (equilateral) hexagon and an (equilateral) octagon are combined. More preferably, the metal portion is of a mesh form constituted by the geometrical figures.

In the invention, the metal portion is most preferably in a mesh form composed of squares.

The line width of the electro-conductive metal portion is preferably 20 μm or less, and the line-to-line distance is preferably 100 μm or more. Also, the electro-conductive portion may have a sub-portion having a line width of more than 20 μm for the purpose of grounding. Further, in view of making the metal portion inconspicuous, it is more preferred for the electro-conductive portion to have a line width of less than 15 μm.

As to the thickness of the electro-conductive metal portion, a thinner metal portion is more preferred for the use of display panel because it serves to enlarge the viewing angle. The thickness is preferably from 1 μm to 20 μm, more preferably from 1 μm to 13 μm, still more preferably from 2 to 10 μm, most preferably from 3 to 7 μm. Also, the electro-conductive portion is preferably in a patterned form. The electro-conductive metal portion may be a single layer or may be of a layered structure composed of two or more layers.

In view of visible light transmittance, the electro-conductive metal portion in the invention has an opening ratio of preferably 85% or more, more preferably 90% or more, most preferably 95% or more. The term “opening ratio” as used herein means the proportion of area free of the fine wires constituting the mesh based on the total area. For example, an opening ratio of a square lattice mesh of 10 μm in line width and 200 μm in pitch is about 90%. Additionally, there is no particular limit as to the upper limit of the opening ratio of the electro-conductive metal portion in the invention. However, in view of the relation between the surface resistance value and the line width, the opening ratio is preferably 98% or less.

### [Rust Inhibitor]

Next, the rust inhibitor to be used in the invention will be described below.

The rust inhibitor to be employed in the present invention is preferably a 5-membered cyclic azole compound having an N—H structure of an organic mercapto compound. The N—H structure means a nitrogen-hydrogen bond contained in azoles, in which the hydrogen is dissociable.

Preferred examples of the 5-membered cyclic azole compound having an N—H structure include tetrazoles, triazoles, imidazoles, thiadiazoles, benzimidazoles, and tetrazaindenes.

Such rings may have a substituent, which is represented by Lₙ-Rₘ.

L represents a single bond, a divalent aliphatic group, a divalent aromatic hydrocarbon group, a divalent heterocyclic group or a linking moiety formed by a combination thereof.

L is preferably a single bond, an alkylene group containing 1 to 10 carbon atoms (such as methylene, ethylene, propylene, butylene, isopropylene, 2-hydroxypropylene, hexylene or octylene group), an alkenylene group containing 2 to 10 carbon atoms (such as vinylene, propenylene, or butynylene group), an aralkylene group containing 7 to 12 carbon atoms (such as phenethylene group), an arylene group containing 6 to 12 carbon atoms (such as phenylene, 2-chlorophenylene, 3-methoxyphenylene or naphthylene group), a divalent heterocyclic group containing 1 to 10 carbon atoms (such as pyridyl, thienyl, furyl, triazolyl or imidazolyl group), a group formed by an arbitrary combination of a single bond and these groups, or an arbitrary combination with —CO—, —SO₂—, —NR₂₀₂—, —O— or —S—. R₂₀₂ represents a hydrogen atom, an alkyl group containing 1 to 6 carbon atoms (such as methyl, ethyl, butyl or hexyl group), an aralkyl group containing 7 to 10 carbon atoms (such as benzyl or phenethyl group), or an aryl group containing 6 to 10 carbon atoms (such as phenyl, 4-methylphenyl or 2-methylphenyl group). It is particularly preferably a single bond.

R may be a substituent such as a nitro group, a halogen atom (such as a chlorine atom or a bromine atom), a mercapto group, a cyano group, a substituted or non-substituted alkyl group (such as methyl, ethyl, propyl, t-butyl, or cyanoethyl group), an aryl group (such as phenyl, 4-methanesulfonamidephenyl, 4-methylphenyl, 3,4-dichlorophenyl or naphthyl group), an alkenyl group (such as allyl group), an aralkyl group (such as benzyl, 4-methylbenzyl or phenethyl group), a sulfonyl group (such as methanesulfonyl, ethanesulfonyl, or p-toluenesulfonyl group), a carbamoyl group (such as non-substituted carbamoyl, methylcarbamoyl or phenylcarbamoyl group), a sulfamoyl group (such as non-substituted sulfamoyl, methylsulfamoyl or phenylsulfamoyl group), a carbonamide group (such as acetamide or benzamide group), a sulfonamide group (such as methanesulfonamide, benzenesulfonamide or p-toluenesulfonamide group), an acyloxy group (such as acetyloxy or benzoyloxy group), a sulfonyloxy group (such as methanesulfonyloxy group), an ureido group (such as non-substituted ureido, methylureido, ethylureido or phenylureido group), an acyl group (such as acetyl or benzoyl group), an oxycarbonyl group (such as methoxycarbonyl or phenoxycarbonyl group), an oxycarbonylamino group (such as methoxycarbonylamino, phenoxycarbonaylamino or 2-ethylhexyloxycarbonylamino group), or a hydroxyl group.

n and m each represents 0 or an integer of from 1 to 3, and, in the case that n and m each represents 2 or 3, the L's and the R's may be mutually same or different.

Preferred examples of the nitrogen-containing organic heterocyclic compound include imidazole, benzimidazole, benzindazole, and benzotriazole, which may have a substituent such as an alkyl group, a carboxyl group, or a sulfo group.

As the rust inhibitor to be used in the invention, organic mercapto compounds are preferably used. Examples of the organic mercapto compounds include alkylmercapto compounds, arylmercapto compounds and hetero ring mercapto compounds.

The organic mercapto compound is preferably an organic mercapto compound represented by the following formula (2):

Z-SM Formula (2)

wherein Z represents an alkyl group, an aromatic group or a hetero ring group substituted by at least one group selected from the group consisting of a hydroxyl group, —SO₃M² group, —COOM² group (wherein M² represents a hydrogen atom, an alkali metal atom or an ammonium group), an amino group and an ammonio group or by a substituent substituted by at least one member selected from the above-described group, and M represents a hydrogen atom, an alkali metal atom or an amidino group (optionally forming a hydrohalogenic acid salt or a sulfonate).

Also, organic mercapto compounds represented by the following formulae (1), (3) to (5) are also preferred. Particularly, compounds represented by the formula (1) are preferred.

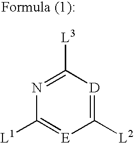

In the formula (1), -D= and -E= each independently represents —CH═ group, —C(R^{o})═ group or —N═ group, R^{o} represents a substituent, and L¹, L² and L³ each independently represents a hydrogen atom, a halogen atom or any substituent connected to the ring through a carbon atom, a nitrogen atom, an oxygen atom, a sulfur atom or a phosphorus atom, provided that at least one of L¹, L², L³ and R^{o} is —SM group (wherein M represents an alkali metal atom, a hydrogen atom or an ammonium group). Additionally, when one of -D= and -E= is group —N═, -D=represents group —CH═ or —C(R^{o})═, and -E= represents group —N═.

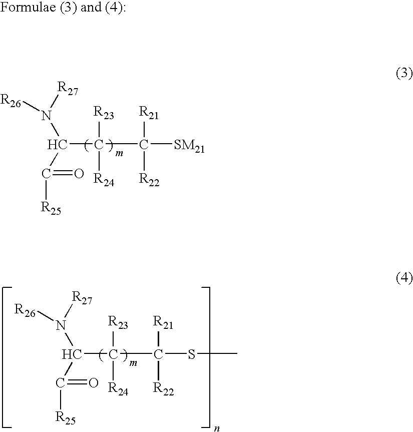

In the formulae (3) and (4), R₂₁ and R₂₂ each represents a hydrogen atom or an alkyl group, provided that R₂₁ and R₂₂ do not represent a hydrogen atom at the same time and that the alkyl group may have a substituent, R₂₃ and R₂₄ each represents a hydrogen atom or an alkyl group, R₂₅ represents a hydroxyl group (or its salt), an amino group, an alkyl group or a phenyl group, R₂₆ and R₂₇ each represents a hydrogen atom, an alkyl group, an acyl group or —COOM₂₂, provided that R₂₆ and R₂₇ do not represent a hydrogen atom at the same time, M₂₁ represents a hydrogen atom, an alkali metal atom or an ammonium group, M₂₂ represents a hydrogen atom, an alkyl group, an alkali metal atom, an aryl group or an aralkyl group, m represents 0, 1 or 2, and n represents 2.

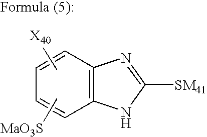

In the formula (5), X₄₀ represents a hydrogen atom, a hydroxyl group, a lower alkyl group, a lower alkoxy group, a halogen atom, a carboxyl group or a sulfo group, M₄₁ and Ma each represents a hydrogen atom, an alkali metal atom or an ammonium group.

Compounds represented by the formula (2) will be described below.

In the formula (2), the alkyl group represented by Z is a straight, branched or cyclic alkyl group containing preferably from 1 to 30 carbon atoms, particularly from 2 to 20 carbon atoms, which may further have other substituent than the above-described substituents. The aromatic group represented by Z is a single ring or a condensed ring containing preferably from 6 to 32 carbon atoms, which may further have other substituent than the above-described substituents. The hetero ring group represented by Z is a single ring or a condensed ring containing preferably from 1 to 32 carbon atoms and is preferably a 5- to 6-membered ring containing from 1 to 6 hetero atoms independently selected from among nitrogen, oxygen and sulfur, which may further have other substituent than the above-described substituents. However, in the case where the hetero ring group is tetrazole, it does not have a substituted or unsubstituted naphthyl group as a substituent. Of the compounds represented by the formula (2), compounds wherein Z represents a hetero ring group containing two or more nitrogen atoms are preferred.

Of the compounds represented by the formula (2), preferred compounds are represented by the following formula (2-a).

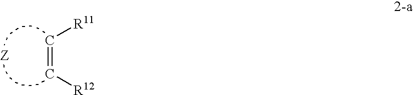

In the above formula, Z represents a group necessary for forming an unsaturated 5-membered hetero ring or 6-membered hetero ring having a nitrogen atom or atoms (e.g., a pyrrole ring, an imidazole ring, a pyrazole ring, a pyrimidine ring, a pyridazine ring or a pyrazine ring), and the compound has at least one —SM group or a thione group and further has at least one substituent selected from the group consisting of a hydroxyl group, —COOM group, —SO₃M group, a substituted or unsubstituted amino group and a substituted or unsubstituted ammonio group. In the formula, R¹¹ and R¹² each independently represents a hydrogen atom, —SM group, a halogen atom, an alkyl group (including alkyl group having a substituent), an alkoxy group (including alkoxy group having a substituent), a hydroxyl group, —COOM group, —SO₃M group, an alkenyl group (including alkenyl group having a substituent), an amino group (including amino group having a substituent), a carbamoyl group (including carbamoyl group having a substituent) or a phenyl group (including phenyl group having a substituent), and R¹¹ and R¹² may be connected to each other to form a ring. The ring to be formed is a 5- or 6-membered ring and is preferably a nitrogen-containing hetero ring. M is the same as the formerly defined M in the formula (2). Preferably, Z is a group forming a hetero ring compound having two or more nitrogen atoms, which may further have other substituent than the —SM group or the thione group. Examples of such substituent include a halogen atom, a lower alkyl group (including alkyl group having a substituent; an alkyl group containing 5 or less carbon atoms such as a methyl group or an ethyl group being preferred), a lower alkoxy group (including alkoxy group having a substituent; an alkoxy group containing 5 or less carbon atoms such as methoxy, ethoxy or butoxy being preferred), a lower alkenyl group (including alkenyl group having a substituent; an alkenyl group containing 5 or less carbon atoms being preferred), a carbamoyl group and a phenyl group. Of the compounds represented by the formula (2-a), those compounds represented by the following formulae A to F are particularly preferred.

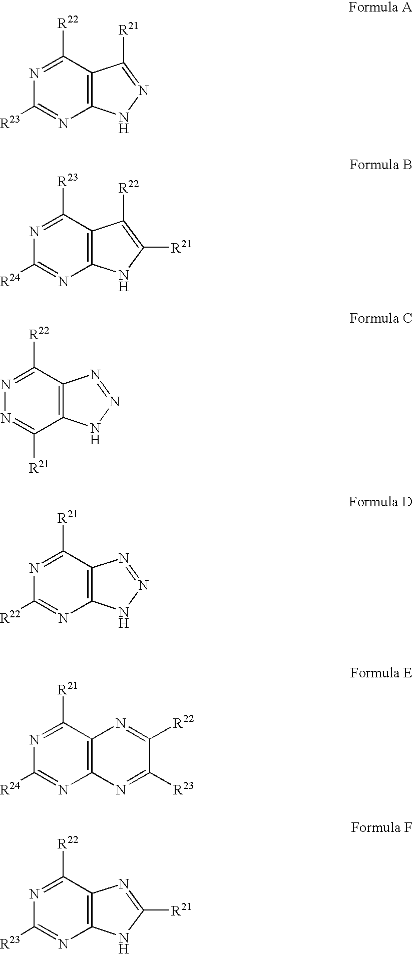

In the above formulae, R²¹, R²², R²³ and R²⁴ each independently represents a hydrogen atom, —SM group, a halogen atom, a lower alkyl group (including alkyl group having a substituent; an alkyl group containing 5 or less carbon atoms such as a methyl group or an ethyl group being preferred), a lower alkoxy group (including alkoxy group having a substituent; alkoxy group containing 5 or less carbon atoms being preferred), a hydroxyl group, —COOM², —SO₃M⁵ group, a lower alkenyl group (including alkeny group having a substituent; alkeny group containing 5 or less carbon atoms being preferred), an amino group, a carbamoyl group or a phenyl group, with at least one being —SM group. M, M² and M⁵ each represents a hydrogen atom, an alkali metal atom or an ammonium group. In particular, it is preferred for the compounds to have a water-soluble group as the substituent other than —SM such as a hydroxyl group, —COOM², —SO₃M⁵ group or an amino group.

The amino group represented by R²¹, R²², R²³ or R²⁴ is a substituted or unsubstituted amino group, with a preferred substituent being a lower alkyl group. The ammonium group represented by M, M² or M⁵ is a substituted or unsubstituted ammonium group, with an unsubstituted ammonium group being preferred.

Specific examples of the compound represented by the formula (2) are shown below which, however, are not limitative at all.

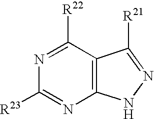

| | R²¹ | R²² | R²³ |
|---|---|---|---|
| 2-1 | H | OH | SH |
| 2-2 | H | SH | OH |
| 2-3 | OH | H | SH |
| 2-4 | OH | H | SH |
| 2-5 | H | NH₂ | SH |
| 2-6 | H | SK | SO₃K |
| 2-7 | COOH | H | SH |

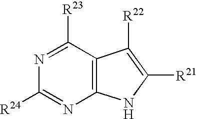

| | R²¹ | R²² | R²³ | R²⁴ |
|---|---|---|---|---|
| 2-8 | H | H | OH | SH |
| 2-9 | Cl | H | NH₂ | SH |
| 2-10 | SH | H | NH₂ | H |
| 2-11 | H | H | COOH | SH |
| 2-12 | OH | H | H | SH |
| 2-13 | H | H | OH | SH |
| 2-14 | SH | H | SH | SO₃H |

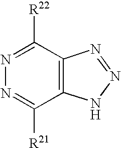

| | R²¹ | R²² |
|---|---|---|
| 2-15 | SH | OH |
| 2-16 | NH₂ | SH |
| 2-17 | SH | COOH |
| 2-18 | SH | SO₃H |
| 2-19 | SH | OH |

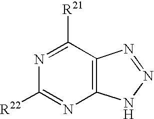

| | R²¹ | R²² |
|---|---|---|
| 2-20 | SH | COOH |
| 2-21 | NH₂ | SH |
| 2-22 | SH | COOH |
| 2-23 | SH | SO₃H |
| 2-24 | SH | OH |

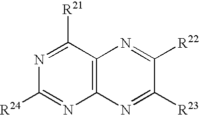

| | R²¹ | R²² | R²³ | R²⁴ |
|---|---|---|---|---|
| 2-25 | NH₂ | H | H | SH |
| 2-26 | COOH | H | SH | SH |
| 2-27 | OH | H | H | SH |
| 2-28 | H | NH₂ | H | SH |
| 2-29 | SH | COOH | H | H |
| 2-30 | H | H | SO₃H | SH |

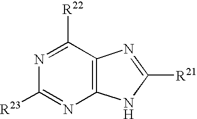

| | R²¹ | R²² | R²³ |
|---|---|---|---|
| 2-31 | SH | OH | H |
| 2-32 | SH | H | COOH |
| 2-33 | H | OH | SH |
| 2-34 | SO₃H | SH | SH |
| 2-35 | H | SH | SO₃H |
| 2-36 | NH₂ | H | SH |
| 2-37 | NH₂ | SH | H |
| 2-38 | H | NH₂ | SNa |
| 2-39 | SH | NH₂ | H |

Compounds represented by the formulae (1), (3) to (5) will be described below.

Compounds represented by the formula (1) will be described in detail below. In the formula (1), wherein -D= and -E= each independently represents —CH═ group, —C(R^{o})═ group or —N═ group, with R^{o} representing a substituent. L¹, L² and L³ may be the same or different and each independently represents a hydrogen atom, a halogen atom or any substituent connected to the ring through a carbon atom, a nitrogen atom, an oxygen atom, a sulfur atom or a phosphorus atom, provided that at least one of L¹, L², L³ and R^{o} is —SM group (wherein M represents an alkali metal atom, a hydrogen atom or an ammonium group). Additionally, when one of -D= and -E= is —N═ group, -D= represents —CH═ group or —C(R^{o}) group, and -E= represents —N═ group.

As any substituent represented by L¹, L² or L³ and a substituent represented by R^{o}, there can be illustrated a halogen atom (a fluorine atom, a chlorine atom, a romine atom or an iodine atom), an alkyl group (including an aralkyl group, a cycloalkyl group and an active methine group), an alkenyl group, an alkynyl group, an aryl group, a hetero ring group, a hetero ring group containing a quarternized nitrogen atom (e.g., a pyridinio group), an acyl group, an alkoxycarbonyl group, an aryloxycarbonyl group, a carbamoyl group, a carboxyl group or its salt, a sulfonylcarbamoyl group, an acylcarbamoyl group, a sulfamoylcarbamoyl group, a carbazoyl group, an oxalyl group, an oxamoyl group, a cyano group, a thiocarbamoyl group, a hydroxyl group, an alkoxy group (including a group having repeated ethylene oxy group unit or propylene oxy group unit), an aryoxy group, a hetero ring oxy group, an acyloxy group, an (alkoxy or aryloxy)carbonyloxy group, a carbamoyloxy group, a sulfonyloxy group, an amino group, an (alkyl, aryl or hetero ring)amino group, a hydroxyamino group, an N-substituted, saturated or unsaturated, nitrogen-containing hetero ring group, an acylamino group, a sulfonamido group, a ureido group, a thioureido group, an imido group, an (alkoxy or aryloxy)carbonylamino group, a sulfamoylamino group, a semicarbazido group, a thiosemicarbazido group, a hydrazino group, an ammonio group, an oxamoylamino group, an (alkyl or aryl)sulfonylureido group, an acylureido group, an acylsulfamoylamino group, a nitro group, a mercapto group, an (alkyl, aryl or hetero ring)thio group, an (alkyl or aryl)sulfonyl group, an (alkyl or aryl)sulfinyl group, a sulfo group or its salt, a sulfamoyl group, an acylsulfamoyl group, a sulfonylsulfamoyl group or its salt and a group having a structure of phosphoric acid amide or phosphoric acid ester. These substituents may further be substituted by these substituents.

As any substituent represented by L¹, L² or L³ and a substituent represented by R^{o}, more preferred are those substituents which contain from 0 to 15 carbon atoms, and are a halogen atom, an alkyl group, an aryl group, a hetero ring group, an acyl group, an alkoxycarbonyl group, a carbamoyl group, a carboxyl group or its salt, a cyano group, an alkoxy group, an aryloxy group, an acyloxy group, an amino group, an (alkyl, aryl or hetero ring)amino group, a hydrozyamino group, an N-substituted, saturated or unsaturated, nitrogen-containing hetero ring group, an acylamino group, a sulfonamido group, a ureido group, a thioureido group, a sulfamoylamino group, a nitro group, a mercapto group, an (alkyl, aryl or hetero ring)thio group, a sulfo group or its salt and a sulfamoyl group, still more preferred are an alkyl group, an aryl group, a hetero ring group, an alkoxycarbonyl group, a carbamoyl group, a carboxyl group or its salt, an alkoxy group, an aryloxy group, an acyloxy group, an amino group, an (alkyl, aryl or hetero ring)amino group, a hydroxyamino group, an N-substituted, saturated or unsaturated, nitrogen-containing hetero ring group, an acylamino group, a sulfonamido group, a ureido group, a thioureido group, a sulfamoylamino group, a mercapto group, an (alkyl, aryl or hetero ring)thio group and a sulfo group or its salt, most preferably an amino group, an alkyl group, an aryl group, an alkoxy group, an aryloxy group, an alkylamino group, an arylamino group, an alkylthio group, an arylthio group, a mercapto group, a carboxyl group or its salt and a sulfo group or its salt. In the formula (1), L¹, L², L³ and R^{o} may be connected to each other to form a condensed ring wherein a hydrocarbon ring, a hetero ring and/or an aromatic ring are condensed with each other.

In the formula (1), at least one of L¹, L², L³ and R^{o} represents —SM group (wherein M represents an alkali metal atom, a hydrogen atom or an ammonium group). The alkali metal atom is specifically Na, K, Li, Mg, Ca or the like which exists as a counter ion for —S⁻. M is preferably a hydrogen atom, an ammonium group, Na⁺ or K⁺, with a hydrogen atom being particularly preferred. Of the compounds represented by the formula (1), those compounds are preferred which are represented by the following formulae (1-A) or (1-B).

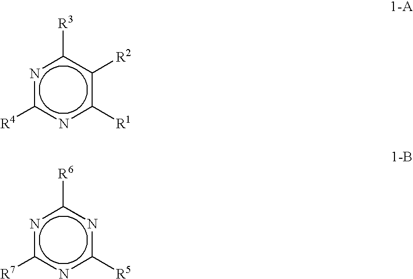

Next, the formula (1-A) will be described in detail below. R¹ to R⁴ each independently represents a hydrogen atom, a halogen atom or any substituent connected to the ring through a carbon atom, a nitrogen atom, an oxygen atom, a sulfur atom or a phosphorus atom, and is the same as defined with respect to L¹, L², L³ with a preferred scope thereof being also the same as described there. However, R¹ and R³ do not represent a hydroxyl group. R¹ to R⁴ may be the same or different, with at least one of them being —SM group (wherein M represents a hydrogen atom, an alkali metal atom or an ammonium group). Also, R¹ and R² may be connected to each other to form a condensed ring wherein a hydrocarbon ring, a hetero ring or an aromatic ring is condensed.

In the formula (1-A), at least one of R¹ to R⁴ is —SM group. More preferably, at least two of R¹ to R⁴ are —SM group. In the case where at least two of R¹ to R⁴ are —SM group, preferably R⁴ and R¹, or R⁴ and R³ are —SM group.

In the invention, of the compounds represented by the formula (1-A), those compounds are particularly preferred which are represented by the following formulae (1-A-1) to (1-A-3).

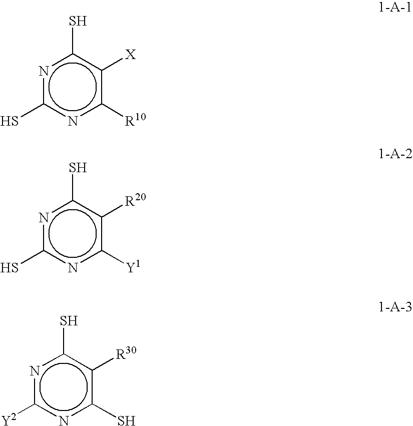

In the formula (1-A-1), R¹⁰ represents a mercapto group, a hydrogen atom or any substituent, and X represents a water-soluble group or a substituent substituted by a water-soluble group. In the formula (1-A-2), Y¹ represents a water-soluble group or a substituent substituted by a water-soluble group, and R²⁰ represents a hydrogen atom or any substituent. In the formula (1-A-3), Y² represents a water-soluble group or a substituent substituted by a water-soluble group, and R³⁰ represents a hydrogen atom or any substituent. However, R¹⁰ and Y¹ do not represent a hydroxyl group.

Next, compounds represented by the formulae (1-A-1) to (1-A-3) will be described in detail below.

In the formula (1-A-1), R¹⁰ represents a mercapto group, a hydrogen atom or any substituent. Here, as the any substituent, there can be illustrated those which have been described with respect to R¹ to R⁴ in the formula (1-A). R¹⁰ is preferably a group selected from among a mercapto group, a hydrogen atom and a substituent containing from 0 to 15 carbon atoms. That is, there can be illustrated an amino group, an alkyl group, an aryl group, an alkoxy group, an aryloxy group, an acylamino group, a sulfonamido group, an alkylthio group, an arylthio group, an alkylamino group and an arylamino group. In the formula (1-A-1), X represents a water-soluble group or a substituent substituted by a water-soluble group. Here, the water-soluble group is a sulfonic acid group or a carboxylic acid group, or the salt thereof, or a group containing a dissociative group capable of being dissociated partly or completely in an alkaline developing solution. Specifically, X represents a sulfo group (or its salt), a carboxyl group (or its salt), a hydroxyl group, a mercapto group, an amino group, an ammonio group, a sulfonamido group, an acylsulfamoyl group, a sulfonylsulfamoyl group, an active methine group or a substituent containing such group. Additionally, in the invention, the active methine group means a methyl group substituted by two electron attractive groups, and specific examples thereof include a dicyanomethyl group, an α-cyano-α-etoxycarbonylmethyl group and an α-acetyl-α-ethoxycarbonylmethyl group. As the substituent represented by X in the formula (1-A-1) is the above-described water-soluble group or a substituent substituted by the water-soluble group. The substituent is a substituent containing from 0 to 15 carbon atoms, and examples thereof include an alkyl group, an aryl group, a hetero ring group, an alkoxy group, an aryloxy group, a hetero ring oxy group, an acyloxy group, an (alkyl, aryl or hetero ring)amino group, an acylamino group, a sulfonamido group, a ureido group, a thioureido group, an imido group, a sulfamoylamino group, an (alkyl, aryl or hetero ring)thio group, an (alkyl or aryl)sulfonyl group, a sulfamoyl group and an amino group, with an alkyl group containing from 1 to 10 carbon atoms (particularly, a methyl group substituted by an amino group), an aryl group, an aryloxy group, an amino group, an (alkyl, aryl or hetero ring)amino group and an (alkyl, aryl or hetero ring)thio group being preferred.

Of the compounds represented by the formula (1-A-1), compounds represented by the following formula (1-A-1-a) are more preferred.

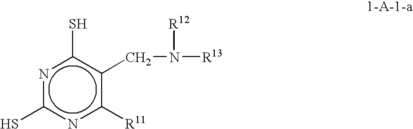

In the formula, R¹¹ is the same as defined with respect to R¹⁰ in the formula (1-A-1), and a preferred scope thereof is also the same as described there. R¹² and R¹³ may be the same or different and each represents a hydrogen atom, an alkyl group, an aryl group or a hetero ring group, provided that at least one of R¹² and R¹³ has at least one water-soluble group. Here, the water-soluble group means a sulfo group (or its salt), a carboxyl group (or its salt), a hydroxyl group, a mercapto group, an amino group, an ammonio group, a sulfonamido group, an acylsulfamoyl group, a sulfonylsulfamoyl group, an active methine group or a substituent containing such group, with a sulfo group (or its salt), a carboxyl group (or its salt), a hydroxyl group and an amino group being preferred. R¹² and R¹³ are preferably an alkyl group or an aryl group and, when R¹² and R¹³ are an alkyl group, the alkyl group is preferably a substituted or unsubstituted alkyl group containing from 1 to 4 carbon atoms. As the substituent, a water-soluble group is preferred, with a sulfo group (or its salt), a carboxyl group (or its salt), a hydroxyl group or an amino group being particularly preferred. When R¹² and R¹³ are an aryl group, the aryl group is preferably a substituted or unsubstituted phenyl group containing from 6 to 10 carbon atoms. As the substituent, a water-soluble group is preferred, with a sulfo group (or its salt), a carboxyl group (or its salt), a hydroxyl group or an amino group being particularly preferred. When R¹² and R¹³ each represents an alkyl group or an aryl group, they may be connected to each other to form a ring structure. It is also possible to form a saturated hetero ring by the ring structure.

In the formula (1-A-2), Y¹ represents a water-soluble group or a substituent substituted by a water-soluble group, and is the same as defined with respect to X in the formula (1-A-1). More preferably, the water-soluble group or the substituent substituted by the water-soluble group represented by Y¹ in the formula (1-A-2) is an active methine group or the following group substituted by a water-soluble group, i.e., an amino group, an alkoxy group, an aryloxy group, an alkylthio group, an arylthio group, an alkyl group or an aryl group. Still more preferably, Y¹ is an active methine group or an (alkyl, aryl or hetero ring)amino group substituted by a water-soluble group, with the water-soluble group being particularly preferably a hydroxyl group, a carboxyl group or its salt, or a sulfo group or its salt. Y¹ is particularly preferably an (alkyl, aryl or hetero ring)amino group substituted by a hydroxyl group, a carboxyl group (or its salt) or a sulfo group (or its salt), which can be represented by —N(R⁰¹)(R⁰²) wherein R⁰¹ and R⁰² are the same as defined with respect to R¹² and R¹³ in the formula (1-A), with a preferred scope thereof being also the same as described there.

In the formula (1-A-2), R²⁰ represents a hydrogen atom or any substituent. As the “any substituent”, there can be illustrated the same ones as have been described with respect to R¹ to R⁴. R²⁰ is preferably a group selected from among a hydrogen atom and substituents containing from 0 to 15 carbon atoms. That is, as R²⁰, there can be illustrated a hydroxyl group, an amino group, an alkyl group, an aryl group, an alkoxy group, an aryloxy group, an acylamino group, a sulfonamido group, an alkylthio group, an arylthio group, an alkylamino group, an arylamino group and a hydroxylamino group. R²⁰ is most preferably a hydrogen atom.

In the formula (1-A-3), Y² represents a water-soluble group or a substituent substituted by a water-soluble group, and R³⁰ represents a hydrogen atom or any substituent. Y² and R³⁰ in the formula (1-A-3) are the same as defined with respect to Y¹ in the formula (1-A-2) and R²⁰ in the formula (1-A-2), respectively, with preferred scopes thereof being also the same as described there.

Next, the formula (1-B) will be described in detail below. R⁵ to R⁷ in the formula (1-B) each independently is the same as defined with respect to R¹ to R⁴ in the formula (1-A), with preferred scopes thereof being also described there. Of the compounds represented by the formula (1-B), those compounds are particularly preferred which are represented by the formula (1-B-1):

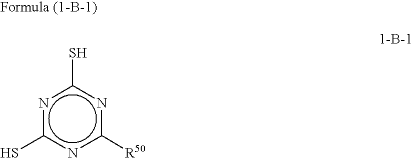

In the formula (1-B-1), R⁵⁰ is the same as defined with respect to R⁵ to R⁷ in the formula (1-B), more preferably is the same water-soluble group or the same substituent substituted by the water-soluble group as defined with respect to X, Y¹ and Y² in the formulae (1-A-1) to (1-A-3). Further, of the compounds represented by the formula (1-B-1), the most preferred compounds are those compounds which are represented by the formula (1-B-1-a):

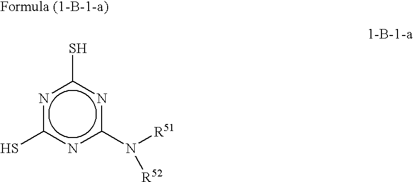

In the formula (1-B-1-a), R⁵¹ and R⁵² are the same as defined with respect to R¹² and R¹³ in the formula (1-A-1-a), and preferred scopes thereof being also the same as described there.

Specific examples of the compounds represented by the formula (1) will be illustrated below. However, the compounds of the formula (1) which can be used in the invention are not limited only to them.

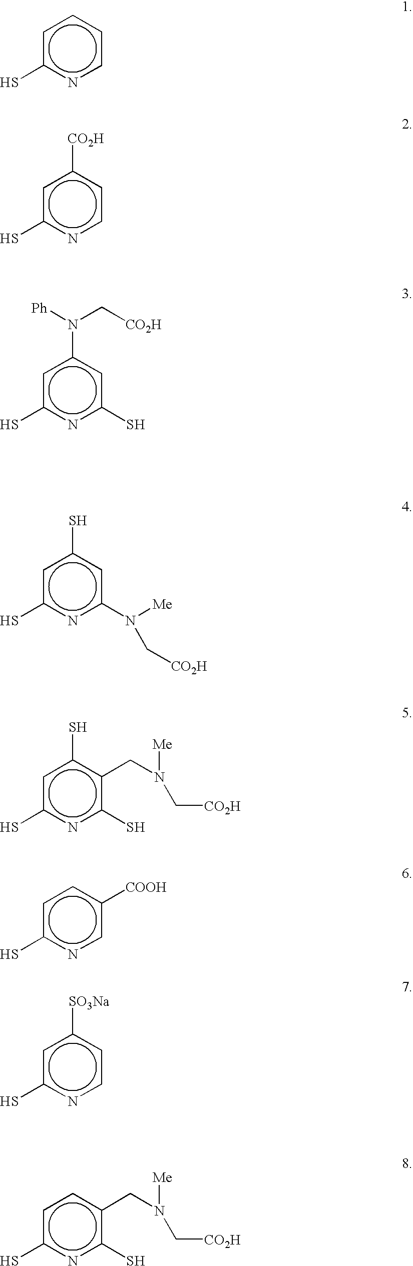

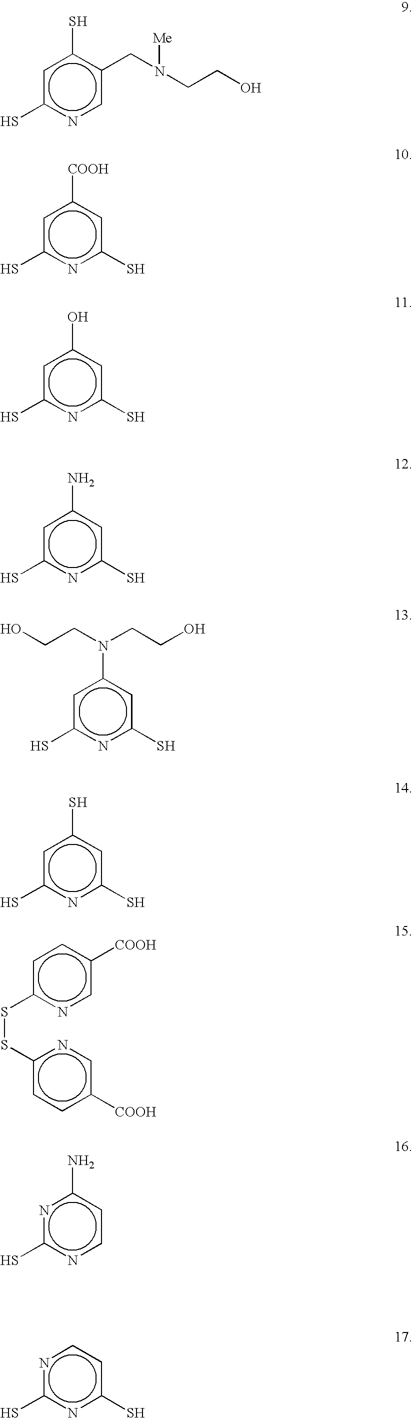

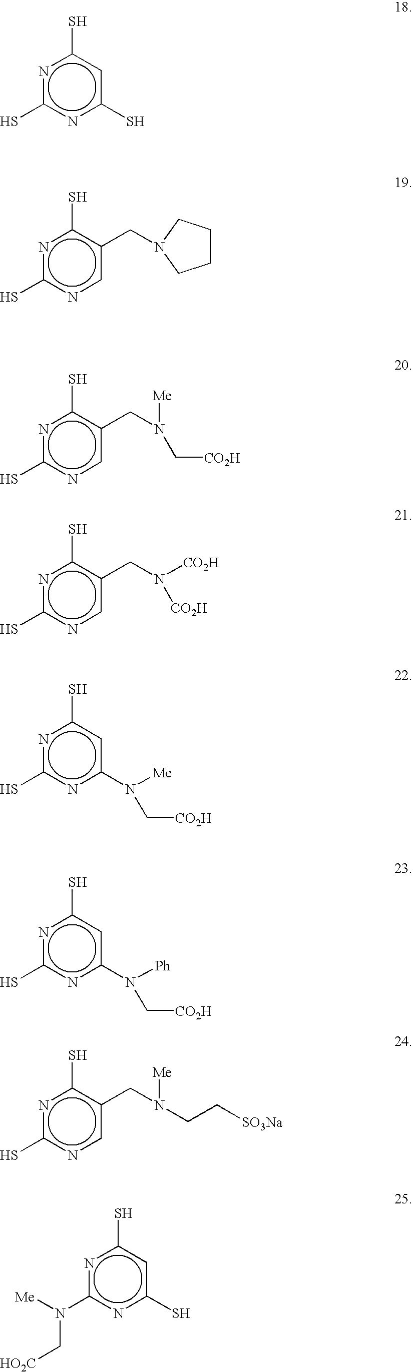

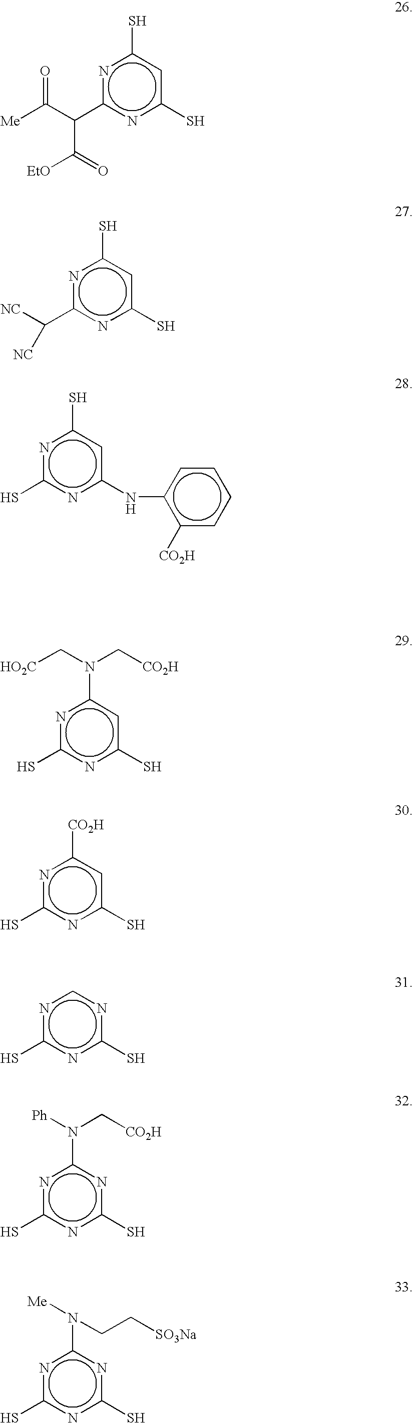

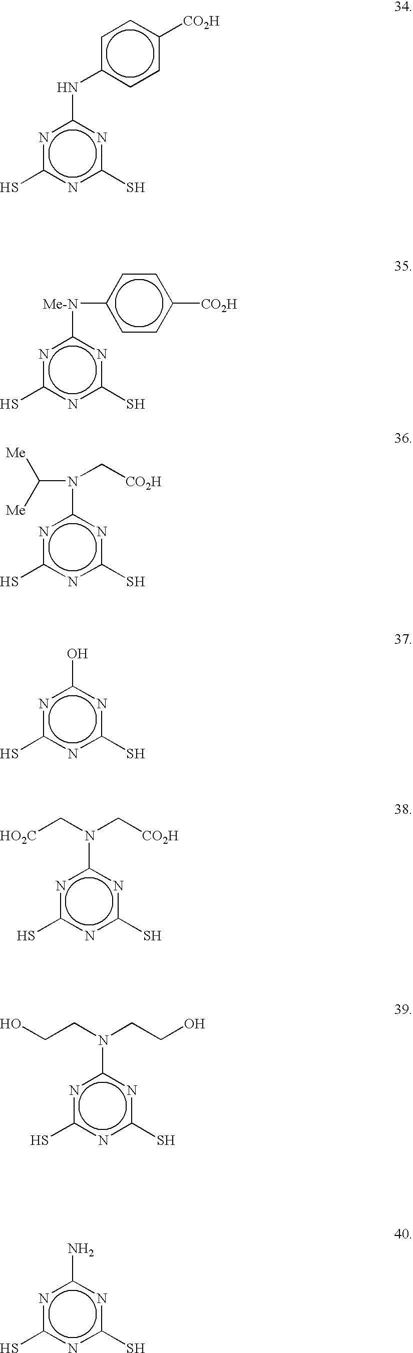

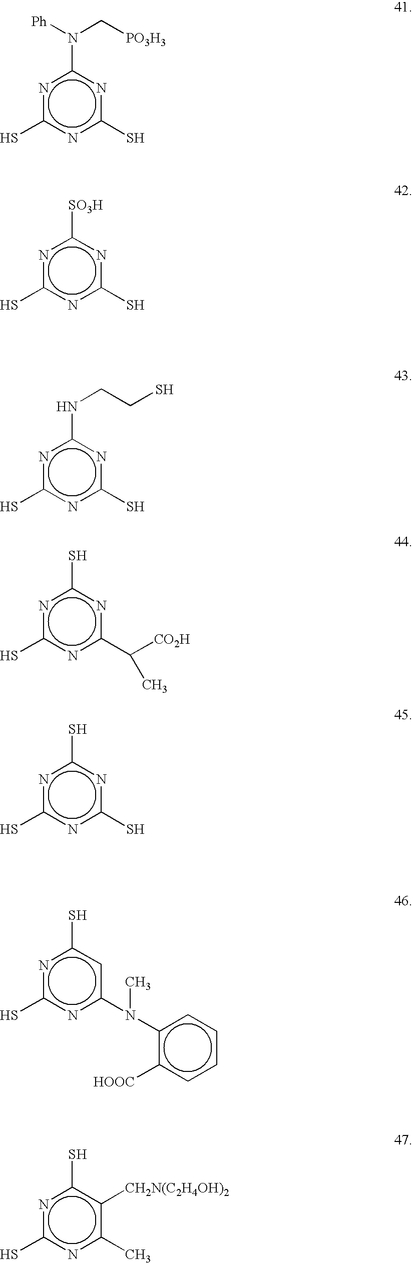

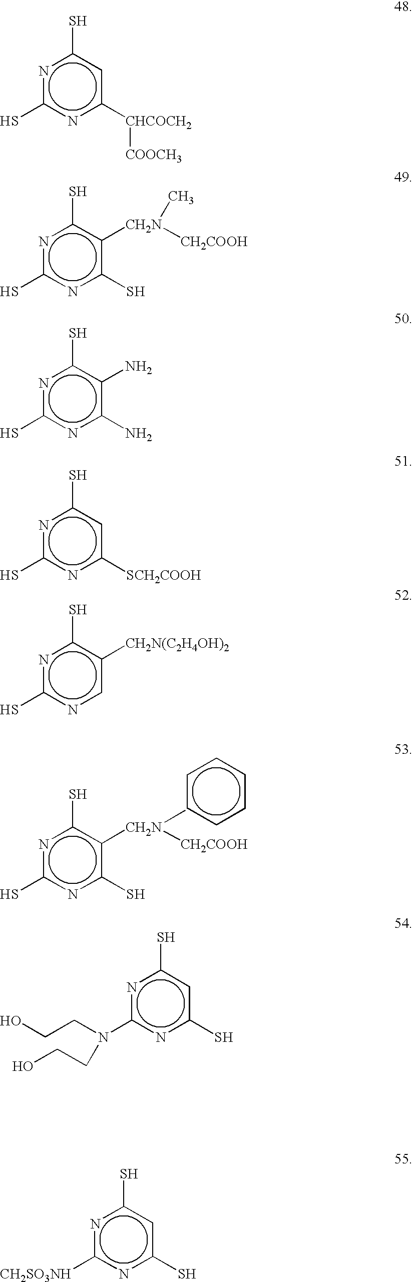

In the formulae (3) and (4), an alkyl group represented by R₂₁, R₂₂, R₂₃, R₂₄ and R₂₅ contains preferably from 1 to 3 carbon atoms and is exemplified by a methyl group, an ethyl group and a propyl group. An alkyl group represented by R₂₆ and R₂₇ contains preferably from 1 to 5 carbon atoms and is exemplified by a methyl group, an ethyl group, a propyl group, a butyl group and a pentyl group, and an acyl group represented by R₂₆ and R₂₇ contains preferably 18 or less carbon atoms and is exemplified by an acetyl group and a benzoyl group. An alkyl group represented by M₂₂ contains preferably from 1 to 4 carbon atoms and is exemplified by a methyl group, an ethyl group, a propyl group and a butyl group, an aryl group represented by M₂₂ is exemplified by a phenyl group and a naphthyl group, and an aralkyl group represented by M₂₂ contains preferably 15 or less carbon atoms and is exemplified by a benzyl group and a phenethyl group.

Various synthesizing processes for the compounds represented by the formula (3) or (4) have been known. For example, the Strecker amino acid synthesis process known as a process for synthesizing an amino acid may be employed, and acetylation of the amino acid is conducted by alternately adding an alkali and acetic anhydride to an aqueous solution of the amino acid.

Next, specific examples of the compounds represented by the formula (3) or (4) will be described below which, however, do not limit the invention in any way.

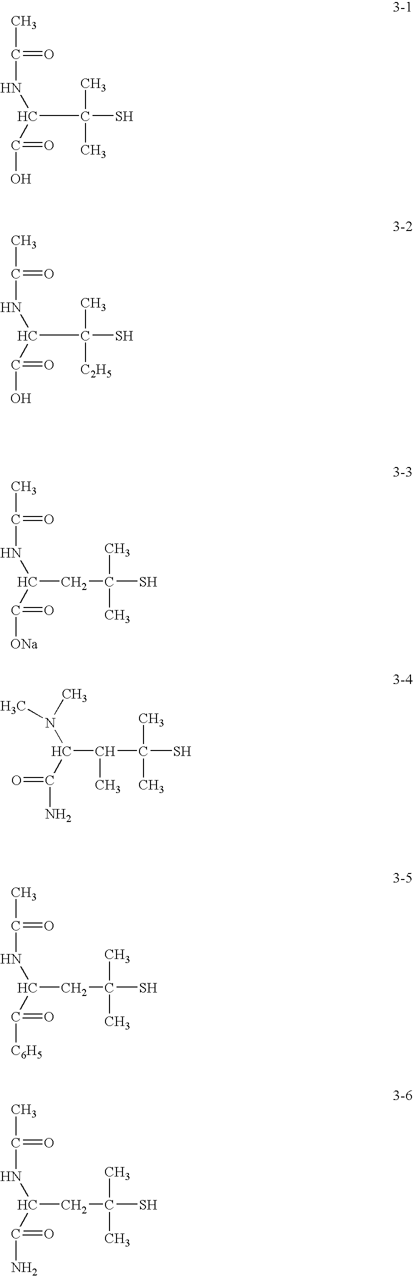

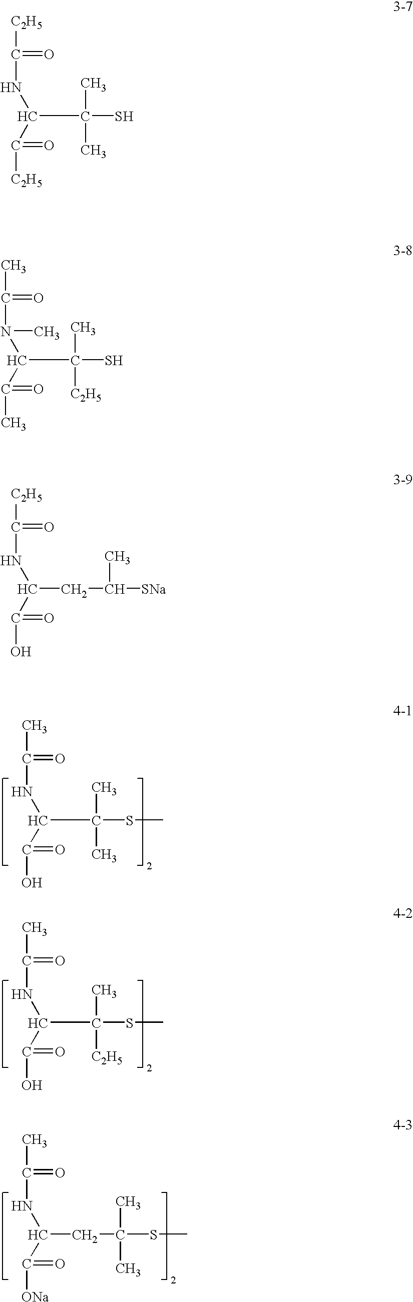

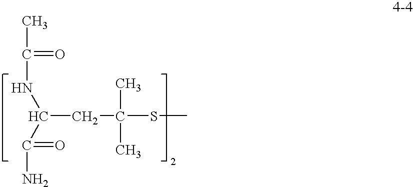

A lower alkyl group represented by X₄₀ in the formula (5) is a straight or branched alkyl group containing preferably from 1 to 5 carbon atoms and is exemplified by a methyl group, an ethyl group and an isopropyl group. Specific examples of the compounds represented by the formula (5) are shown below which, however, are not limitative at all.

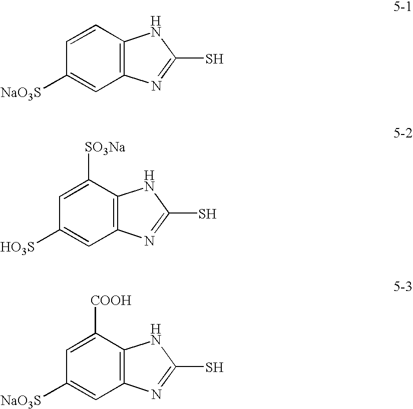

Such rust inhibitor may be employed singly or in a combination of plural kinds.

The rust inhibitor to be employed in the present invention may be impregnated in the electromagnetic wave shielding film by treating it in a bath containing the rust inhibitor, and can be applied to the electro-conductive metal portion, for example by preparing an aqueous solution and dipping therein a transparent substrate on which an electro-conductive metal portion is formed. The rust inhibiting treatment is preferably applied to the electro-conductive metal portion after a sintering process. The aqueous solution of rust inhibitor preferably contains a rust inhibitor compound in a concentration of from 10⁻⁶ to 10⁻¹ mol/L, preferably from 10⁻⁵ to 10⁻² mol/L. Also a pH value of the aqueous solution is preferably regulated at from 2 to 12 (more preferably from 5 to 10), for the purpose of dissolving the rust inhibitor, and the pH regulation may be executed not only by an alkali or an acid such as sodium hydroxide or sulfuric acid ordinarily utilized, but also by a buffer such as phosphoric acid, a salt thereof, a carbonate salt, acetic acid or a salt thereof, boric acid or a salt thereof. The temperature of the aqueous solution is selected within a range of from 0 to 100° C., preferably from 10 to 80° C. in view of dissolving the rust inhibitor.

The rust inhibitor is estimated to be adsorbed on mesh-shaped fine lines, and is considered to exhibit a rust inhibiting effect and a stabilizing effect in such state.

Also in the present invention, the rust inhibitor is preferably provided within a range of from 0.001 to 0.04 g/m² with respect to the metal pattern in terms of the effect of color change resistance and economic efficiency etc. An amount less than 0.001 g/m² is liable to become inferior in the color change resistance. Also an upper limit is selected from an economical reason, as an amount exceeding 0.04 g/m² does not further improve the color change resistance. The range is more preferably from 0.003 to 0.03 g/m², and further preferably from 0.01 to 0.02 g/m².

The content of the rust inhibitor can be regulated by a concentration of the aqueous solution of rust inhibitor, a pH, a temperature and a dipping time. Also the content of the rust inhibitor may be quantified by extracting the rust inhibitor from a sample of the present invention, followed by an analysis such as chromatography or NMR. The extraction of the rust inhibitor may be executed by a suitable method selected for example from a method of oxidizing and dissolving the metal pattern with nitric acid or EDTA.Fe(III) complex, and a method of extraction with an aqueous alkali solution.

The invention relating to a process for producing a light-transmittable electromagnetic wave shielding film will be described in detail below. Additionally, in this specification, “-” (“to”) is used to mean that numbers before and after “-” (“to”) are included as the lower limit value and the upper limit value, respectively.

### [Transparent Substrate]

As the transparent substrate to be used in the invention, there can be used, for example, polyesters such as polyethylene terephthalate (PET) and polyethylene naphthalate; polyolefins such as polyethylene (PE), polypropylene (PP), polystyrene and EVA; vinyl series resins such as polyvinyl chloride and polyvinylidene chloride; and others such as polyether ether ketone (PEEK), polysulfone (PSE), polyether sulfone (PES), polycarbonate (PC), polyamide, polyimide, acrylic resin and triacetyl cellulose (TAC).

In the invention, the transparent plastic substrate is preferably a polyethylene terephthalate film in view of transparency, heat resistance, handling ease and price. The thickness of the transparent plastic substrate is preferably from 5 to 200 μm, more preferably from 10 to 130 μm, still more preferably from 40 to 80 μm, since a substrate with a smaller thickness would have deteriorated handling properties and a substrate with a larger thickness would have a reduced transmittance for visible light.

The substrate is required to have a high transparency because an electromagnetic wave shielding film for use in display panel is required to be transparent. The total visible light transmittance of the transparent plastic substrate for this use is preferably from 70 to 100%, more preferably from 85 to 100%, particularly preferably from 90 to 100%. In the invention, as the transparent plastic substrate, those substrates can also be used which are colored to a degree of not spoiling the effect of the invention.

The transparent plastic substrate in the invention can be used as a single layer, and also can be used as a multi-layer film comprising two or more layers.

In the invention, it is also possible to use a glass plate as the transparent substrate. There exists no limitation as to kind of the glass plate. In the case of using for an electromagnetic wave shielding film for display, however, it is preferred to use a tempered glass having a tempered layer on the surface thereof. In comparison with a non-tempered glass, the tempered glass has a high possibility of preventing breakage. Further, even when broken by any chance, a tempered glass obtained by an air-cooling method produces small broken pieces with non-sharp broken surfaces, thus being preferred in view of safety.

### [Silver Salt-Containing Layer]

In the invention, a silver salt-containing layer is provided on a transparent substrate. The silver salt-containing layer can contain a binder and a solvent in addition to the silver salt.

### <Silver Salt>

As the silver salt to be used in the invention, there are illustrated inorganic silver salts such as silver halide and organic silver salts such as silver acetate. It is preferred to use silver halide which is excellent in characteristic properties as a photo sensor.

The silver halide to be preferably used in the invention will be further described below.

In the invention, silver halide is used to utilize its function as a photo sensor. Techniques used for silver salt photographic films or photographic printing paper, films for making printing plates, and emulsion masks for a photo mask, which are related to silver halide, can be applied as such to the invention.

The halogen element to be contained in the silver halide may be any of chlorine, bromine, iodine and fluorine and may be a mixture thereof. For example, silver halides containing AgCl, AgBr or AgI as a major component are preferably used, with a silver halide containing AgBr as a major component being more preferably used.

The term “silver halide containing AgBr (silver bromide) as a major component” as used herein means a silver halide wherein a mol fraction of bromide ion in the silver halide composition amounts to 50% or more. The silver halide grains containing AgBr as a major component may contain iodide ion or chloride ion in addition to bromide ion.

The silver halide is in a solid grain form and, in view of image quality of a pattern-wise metal silver layer to be formed after exposure and development processing, the average particle size of silver halide grains is preferably from 0.1 to 1000 nm (1 μm), more preferably from 0.1 to 100 nm, still more preferably from 1 to 50 nm, in equivalent-sphere diameter. Additionally, the term “equivalent-sphere diameter” of silver halide grain as used herein means a diameter of spherical particles having the same volume as the grain.

The silver halide grains are not particularly limited as to the shape thereof, and may be in various shapes such as a spherical shape, a cubic shape, a tabular shape (e.g., a hexagonal tabular shape, a triangular tabular shape or a quadrilateral tabular shape), an octahedral shape and a tetradecahedral shape).

The silver halide to be used in the invention may further contain other elements. For example, in photographic emulsions, it is useful to dope with a metal ion which is used for obtaining a contrasty emulsion. In particular, a transition metal such as rhodium ion or iridium ion is preferably used since it is liable to produce distinct discrimination between exposed area and unexposed area upon formation of a metal silver image. The transition metal ion represented by rhodium ion or iridium ion can be a compound having a varying ligand. Examples of such ligand include cyanaide ion, halide ion, thiocyanato ion, nitrosil ion, water and hydroxide ion. Examples of specific compounds include K₃Rh₂Br₉ and K₂IrCl₆.

In the invention, the content of the rhodium compound and/or the iridium compound to be incorporated in the silver halide is preferably from 10⁻¹⁰ to 10⁻² mol/mol Ag, more preferably from 10⁻⁹ to 10⁻³ mol/mol Ag, per mol of silver of silver halide.

In addition, in the invention, a silver halide containing Pd(II) ion and/or Pd metal can also be preferably used. Pd may be uniformly distributed within the silver halide grains, but is preferably contained in the vicinity of the surface layer of the silver halide grains. The term “being contained in the vicinity of the surface layer of the silver halide grains” as used herein means that there exists a layer having a higher palladium content than in other layer at a position within a depth of 50 nm from the surface of the silver halide grains. Such silver halide grains can be prepared by adding Pd in the course of forming silver halide grains. It is preferred to add Pd after adding silver ion and halide ion in amounts of 50% or more, respectively, of the total amounts thereof. It is also preferred for Pd(II) ion to be allowed to exist in the surface layer of silver halide grains by, for example, a method of adding Pd(II) ion upon post-ripening.

The Pd-containing silver halide grains accelerate physical development or non-electrode plating, and increase production efficiency of a desired light-transmittable electromagnetic wave shielding film, thus contributing to reduction of production cost. Pd is well known as a catalyst for non-electrode plating. In the invention, Pd can be localized in the surface layer of the silver halide grains, thus extremely expensive Pd being saved.

In the invention, the content of Pd ion and/or Pd metal to be incorporated in silver halide is preferably from 10⁻⁴ to 0.5 mol/mol Ag, more preferably from 0.01 to 0.3 mol/mol Ag, per mol of silver of silver halide.

Examples of the Pd compound to be used include PdCl₄ and Na₂PdCl₄.

In the invention, in order to more improve sensitivity as a photo sensor, the silver halide may be subjected to chemical sensitization which has been conducted with photographic emulsions. As such chemical sensitization, noble metal sensitization such as gold sensitization, chalcogen sensitization such as sulfur sensitization, and reduction sensitization can be utilized.

As the emulsion usable in the invention, there can preferably be used, for example, emulsions for color negative-working films described in Examples of JP-A-11-305396, JP-A-2000-3221698, JP-A-13-281815 and JP-A-2002-72429, emulsions for color reversal films described in JP-A-2002-214731, and emulsions for color photographic printing papers described in JP-A-2002-107865.

### <Binder>

In the silver salt-containing layer of the invention, a binder can be used for the purpose of uniformly dispersing silver salt grains and assisting adhesion between the silver salt-containing layer and the transparent substrate. In the invention, either of a non-water-soluble polymer and a water-soluble polymer can be used as the binder, with a water-soluble polymer being preferably used.

Examples of the binder include gelatin, polyvinyl alcohol (PVA), polyvinyl pyrrolidone (PVP), polysaccharides such as starch, cellulose and its derivative, polyethylene oxide, polyvinylamine, chitosan, polylysine, polyacrylic acid, polyalginic acid, polyhyaluronic acid and carboxy cellulose. These have neutral, anionic or cationic properties depending upon the ionic properties of the functional group thereof.

The content of the binder to be contained in the silver salt-containing layer of the invention is not particularly limited and can properly be decided within a range where dispersibility and adhesion properties thereof can be exhibited. The content of the binder in the silver salt-containing layer is preferably from 1/4 to 100, more preferably from 1/3 to 10, still more preferably from 1/2 to 2, most preferably from 1/1 to 2, in terms of Ag/binder volume ratio. Incorporation of the binder in a content of 1/4 or more in terms of Ag/binder volume ratio facilitates mutual contact between metal particles in the step of physical development and/or plating treatment and can provide a high electro-conductivity, thus being preferred.

### <Solvent>

The solvent to be used for the silver salt-containing layer of the invention is not particularly limited, and examples thereof include water, organic solvents (e.g., alcohols such as methanol; ketones such as acetone; amides such as formamide; sulfoxides such as dimethylsulfoxide; esters such as ethyl acetate; and ethers), ionic liquids, and mixed solvents thereof.

The content of the solvent to be used in the silver salt-containing layer of the invention is preferably from 30 to 90% by mass, more preferably from 50 to 80% by mass, based on the total mass of the silver salt, binder, etc. contained in the silver-containing layer.

### [Exposure]

In the invention, exposure of the silver salt-containing layer provided on the transparent substrate is conducted. The exposure can be conducted by using electromagnetic wave. Examples of such electromagnetic wave include light such as visible light and UV rays and radiation such as X rays. Further, a light source having a wavelength distribution may be utilized in the exposure, or a light source of a specific wavelength may be used.

As to the light source, scanning exposure using cathode rays (CRT) can be illustrated. In comparison with an apparatus using a laser, a cathode ray tube exposing apparatus is convenient and compact, and is inexpensive. Also, it facilitates adjustment of light axis and color. As a cathode ray tube for use in imagewise exposure, various light-emitting bodies are used as needed which emit a light of a spectral region. For example, one of, or a mixture of two or more of, a red light-emitting body, a green light-emitting body and a blue light-emitting body is used. The spectral region is not limited only to the above-described red, green and blue regions, and a fluorescent body which emits a light of a yellow region, orange region, violet region or infrared region may also be used. In particular, a cathode ray tube which has a mixture of these fluorescent bodies to emit white light is often used. Also, a UV ray lamp is preferred, and g-line of a mercury lamp and i-line of a mercury lamp are utilized as well.

Also, in the invention, exposure can be conducted by using various laser beams. For example, in exposure in the invention, a scanning exposure system using a monocolor high-density light such as a light emitted from a gas laser, a light-emitting diode, a semiconductor laser or a second harmonic generation (SHG) light source comprising a combination of a solid-state laser using a semiconductor laser as an exciting light source and a non-linear optical crystal can preferably be used. Further, a KrF exima laser, an ArF exima laser and an F2 laser can be used as well. In order to make the system compact and inexpensive, exposure is preferably conducted by using a semiconductor laser or a second harmonic generation (SHG) light source comprising a combination of a solid-state laser using a semiconductor laser as an exciting light source and a non-linear optical crystal. In particular, in order to design an apparatus which is compact and inexpensive and which has a long life and a high stability, it is preferred to conduct exposure by using a semiconductor laser.

As a laser light source, specifically, a blue semiconductor laser of 430 to 460 nm in wavelength (reported by Nichia Kagaku in the 48^{th} Oyo Butsurigaku Kankei Rengo Koenkai (Associates Meeting of the 48^{th} Applied Physic Conference), March 2001), a green light-emitting laser of about 530 nm in wavelength obtained by wavelength conversion of a semiconductor laser (oscillation wavelength: about 1060 nm) by SHG crystal of LiNbO₃ having an inverted domain structure in the form of a waveguide channel, a red semiconductor laser of about 685 nm in wavelength (Hitachi type No. HL6738MG) and a red semiconductor laser of about 650 nm in wavelength can preferably be used.

As to the method for pattern-wise exposing the silver salt-containing layer, plane exposure utilizing a photomask or a scanning exposure using a laser beam may be conducted. In this occasion, refraction type exposure using a lens or reflection type exposure using a reflection mirror may be employed. As an exposure manner, contact exposure, proximity exposure, reduction projection exposure and reflection projection exposure may be employed.

### [Development Processing]

In the invention, development processing is performed after exposure of the silver salt-containing layer. To the development processing may be applied ordinary development processing techniques employed for silver salt photographic films, photographic printing papers, films for making a printing plate and an emulsion mask for photomask. There exist no particular limits as to the developing solution, and a PQ developing solution, an MQ developing solution and an MAA developing solution may be used. For example, there can be used developing solutions such as CN-16, CR-56, CP45X, FD-3 and PAPITOL manufactured by Fuji Photo Film Co., Ltd., C-41, E-6, RA-4, D-19 and D-72 manufactured by KODAK, and developing solutions contained in the kits of them, and lith developing solutions such as D-85.

In the invention, a metal silver portion of, preferably, a patterned form is formed by performing the exposure and the development processing, with a light-transmitting portion to be described hereinafter being formed at the same time.

The development processing in the invention may involve fixing treatment to be conducted for the purpose of removing the silver salt in unexposed portions to stabilize. In the fixing treatment in the invention, fixing treatment techniques which are used for silver salt photographic films, photographic printing papers, films for making a printing plate and an emulsion mask for a photomask may be employed.

The developing solution to be used in the development processing can contain an image quality-improving agent for the purpose of improving image quality. Examples of the image quality-improving agent include nitrogen-containing hetero ring compounds such as benzotriazole. In the case of utilizing a lith developing solution, it is particularly preferred to use polyethylene glycol.

The mass of metal silver contained in the exposed portion after development processing is preferably 50% by mass or more, more preferably 80% by mass or more, based on the mass of silver contained in the exposed portion before the exposure. As long as the mass of silver contained in the exposed portion is 50% by mass or more based on the mass of silver contained in the exposed portion before the exposure, there can be obtained a high electro-conductivity, thus such mass being preferred.

In the invention, the gradation after development processing is not particularly limited, but is preferably more than 4.0. In the case where the gradation after development processing exceeds 4.0, the electro-conductivity of the electro-conductive metal portion can be increased while transparency of the light-transmitting portion being kept at a high level. As means for increasing gradation to 4.0 or more, there is illustrated, for example, doping with rhodium ion or iridium ion having been described hereinbefore.

### [Physical Development and Plating Treatment]

In the invention, physical development and/or plating treatment is conducted for electro-conductive metal particles to be supported on the metal silver portion for the purpose of imparting electro-conductivity to the metal silver portion formed by the foregoing exposure and development processing. In the invention, physical development or plating treatment suffices for supporting the electro-conductive metal particles on the metallic portion. Further, it is also possible to support electro-conductive metal particles on the metal silver portion by a combination of the physical development and the plating treatment.

“Physical development” in the invention means to precipitate metal particles onto cores of a metal or a metal compound by reducing a metal ion such as a silver ion with a reducing agent. This physical development is utilized for an instant B&W film and an instant slide film or in production of a printing plate, and the techniques thereof can be employed in the invention.

Also, the physical development may be conducted simultaneously with development processing after exposure or may be conducted separately after development processing.

In the invention, the plating treatment may be non-electrode plating (chemical reduction plating or substitution plating), electrolytic plating, or a combination of non-electrode plating and electrolytic plating. For the non-electrode plating in the invention, known non-electrode plating techniques may be employed. For example, non-electrode plating technique employed for printed wiring boards can be employed, with the non-electrode plating being preferably non-electrode copper plating.

As chemical species contained in a non-electrode copper plating solution, there are illustrated copper sulfate or copper chloride, a reducing agent of formalin or glyoxylic acid, a ligand for copper of EDTA or triethanolamine, and an additive for stabilizing the bath or improving smoothness of a plated film such as polyethylene glycol, yellow prussiate of potash or bipyridine. As the electrolytic copper plating bath, there are illustrated a copper sulfate bath and a copper pyrophosphate bath.

The plating rate upon plating treatment in the invention can be slow and, further, a high-speed plating as fast as 5 μm/hr or more is also possible. In the plating treatment, various additives such as a ligand of EDTA can be used in view of increasing stability of the plating solution.

### [Oxidizing Treatment]

In the invention, the metal silver portion after development processing, and the electro-conductive metal portion formed after the physical development and/or the plating treatment are preferably subjected to oxidizing treatment. In the case where the metal is slightly deposited on the light-transmitting portion, the metal can be removed by the oxidizing treatment to make the transparency of the light-transmitting portion approximately 100%.

As the oxidizing treatment, there are illustrated known methods using various oxidizing agents such as a treatment with Fe(III) ion. The oxidizing treatment can be performed after exposure and development processing of the silver salt-containing layer or after the physical development or the plating treatment. Further, the oxidizing treatment may be conducted both after the development processing and after the physical development or the plating treatment.

In the invention, the metal silver portion after exposure and development processing can be treated with a solution containing Pd. Pd may be a 2-valent palladium ion or metal palladium. This treatment serves to accelerate the non-electrode plating or the physical development.

The light-transmitting portion in the invention is formed simultaneously with formation of the metal silver portion by exposing and development processing the silver salt-containing layer. In view of improving transparency, the light-transmitting portion is preferably subjected to the oxidizing treatment after the development processing and, further, after the physical development or the plating treatment.

Next, the organic mercapto compound to be used in the invention will be described below.

As the organic mercapto compound, there are illustrated alkylmercapto compounds, arylmercapto compounds and hetero ring mercapto compounds.

The organic mercapto compound is preferably an organic mercapto compound used as the rust inhibitor in the invention relating to a light-transmittable electromagnetic wave shielding film which comprises a transparent substrate having provided thereon a printed pattern containing silver as a major component and a rust inhibitor mentioned above. Thus, the organic mercapto compound is preferably an organic mercapto compound represented by the formulae (1) to (5) above, and the same specific examples of the compound represented by the formulae (1) to (5) are exemplified.

The organic mercapto compound to be used in the invention is applied to the electro-conductive metal portion by preparing an aqueous solution of the compound and dipping the transparent substrate having formed thereon the electro-conductive metal portion in the aqueous solution. The aqueous solution of the organic mercapto compound to be used in this occasion contains the compound represented by one of the foregoing formulae (1) to (5) in a concentration of from 10⁻⁶ to 10⁻¹ mol, preferably from 10⁻⁵ to 10⁻² mol, per liter. The dipping time is from 2 seconds to 30 minutes, preferably from 5 seconds to 10 minutes.

The pH of the aqueous solution is adjusted to preferably from 2 to 12 in view of dissolving the organic mercapto compound. In adjusting the pH, ordinary alkalis or acids such as sodium hydroxide or sulfuric acid, and buffering agents such as phosphoric acid or its salts, carbonates, acetic acid or its salts, or boric acid or its salts can be used.

### [Electro-Conductive Metal Portion]

Next, the electro-conductive metal portion in the invention will be described below.

In the invention, the electro-conductive metal portion is formed by subjecting the metal silver portion formed by exposure and development processing to physical development or the plating treatment to thereby support the electro-conductive metal particles on the metal silver portion.

The metal silver is formed in the exposed portion or in the unexposed portion. A silver salt diffusion transfer process (DTR process) utilizing physical development nuclei forms the metal silver in the unexposed portion. In the invention, it is preferred to form the metal silver in the exposed portion in order to enhance transparency.

As the electro-conductive metal particles to be supported on the metal portion, there are illustrated, in addition to above-described silver, particles of metals such as copper, aluminum, nickel, iron, gold, cobalt, tin, stainless steel, tungsten, chromium, titanium, palladium, platinum, manganese, zinc and rhodium, or the alloys of the combination of these metals. In view of electro-conductivity and price, the electro-conductive metal particles are preferably particles of copper, aluminum or nickel. Also, in the case of imparting magnetic field shielding properties, it is preferred to use paramagnetic metal particles as the electro-conductive metal particles.

In view of enhancing contrast and preventing fading due to oxidation of the electro-conductive metal portion with time, the electro-conductive metal particles contained in the electro-conductive metal portion are preferably copper particles, with copper particles at least the surface of which has been blackening-treated being more preferred. The blackening treatment can be conducted by using a method having been conducted in the field of printed wiring boards. For example, the blackening treatment can be performed by dipping in an aqueous solution of sodium chlorite (31 g/l), sodium hydroxide (15 g/l) and trisodium phosphate (12 g/l) at 95° C. for 2 minutes.

The electro-conductive metal portion contains silver in a content of 50% by mass or more, more preferably 60% by mass or more, based on the total mass of the metals contained in the electro-conductive metal portion. When silver is contained in a content of 50% by mass or more, the time required for the physical development and/or the plating treatment can be shortened, the productivity can be improved, and the production cost can be reduced.

Further, in the case of using copper and palladium as the electro-conductive metal particles for forming the electro-conductive metal portion, the sum mass of silver, copper and palladium is preferably 80% by mass or more, more preferably 90% by mass or more, based on the total mass of metals contained in the electro-conductive metal portion.

The electro-conductive metal portion in the invention supports the electro-conductive metal particles, and hence good electro-conductivity can be obtained. Therefore, the surface resistance value of the light-transmittable electromagnetic wave shielding film (electro-conductive metal portion) of the invention is preferably 10 Ω/sq or less, more preferably 2.5 Ω/sq or less, still more preferably 1.5 Ω/sq, most preferably 0.1 Ω/sq or less.

For the use as a light-transmittable electromagnetic wave shielding film, the electro-conductive metal portion in the invention is preferably of a geometrical figure wherein a triangle such as an equilateral triangle, an isosceles triangle or a right triangle, a quadrilateral such as a square, a rectangle, a rhombus, a parallelogram or a trapezoid, an (equilateral) hexagon and an (equilateral) octagon are combined, with a mesh form composed of these geometrical figures being more preferred.

In the invention, a mesh form of lattice composed of equilateral triangle is most preferred.

For the use as a light-transmittable electromagnetic wave shielding film, the line width of the electro-conductive metal portion is preferably 20 μm or less, and the line-to-line distance is preferably 100 μm or more. Also, the electro-conductive portion may have a sub-portion having a line width of more than 20 μm for the purpose of grounding. Further, in view of making the metal portion inconspicuous, it is more preferred for the electro-conductive metal portion to have a line width of less than 15 μm.

As to the thickness of the electro-conductive metal portion, a thinner metal portion is more preferred for the use of display panel because it serves to enlarge the viewing angle. The thickness is preferably from 1 μm to 20 μm, more preferably from 1 μm to 13 μm, still more preferably from 2 to 10 μm, most preferably from 3 to 7 μm. Also, the electro-conductive portion is preferably in a patterned form. The electro-conductive metal portion may be a single layer or may be of a layered structure composed of two or more layers.

In view of visible light transmittance, the electro-conductive metal portion in the invention has an opening ratio of preferably 85% or more, more preferably 90% or more, most preferably 95% or more. The term “opening ratio” as used herein means the proportion of area free of the fine wires constituting the mesh based on the total area. For example, an opening ratio of a square lattice mesh of 10 μm in line width and 200 μm in pitch is about 90%. Additionally, there is no particular limit as to the upper limit of the opening ratio of the metal portion in the invention. However, in view of the relation between the surface resistance value and the line width, the opening ratio is preferably 98% or less.

### [Light-Transmitting Portion]

“Light-transmitting portion” in the invention means other portion of the light-transmittable electromagnetic wave shielding film than the electro-conductive metal portion, which has transparent properties. As has been described hereinbefore, the transmittance in the light-transmitting portion is 90% or more, preferably 95% or more, still more preferably 97% or more, yet more preferably 98% or more, most preferably 99% or more, in terms of transmittance shown by the minimum transmittance in the wavelength region of 380 to 780 nm with subtracting contribution of light absorption and reflection by the transparent substrate.

In view of improving transparency, the light-transmitting portion of the invention preferably does not substantially have the physical development nuclei. As is different from the conventional silver complex salt diffusion transfer process, it is not necessary to diffuse after dissolving unexposed silver halide and converting to a soluble silver complex salt, and hence it is preferred for the light-transmitting portion to have substantially no physical development nuclei.

The term “to have substantially no physical development nuclei” as used herein means that the presence ratio of the physical development nuclei in the light-transmitting portion is in a range of from 0 to 5%.

### [Functional Film]

On the light-transmittable electromagnetic wave shielding film of the invention or on the light-transmittable electromagnetic wave shielding film obtained by the production process of the invention as described above may be provided, as needed, a functional transparent layer having a desired function. For example, for the use of a panel for display, there may be provided a layer having an infrared ray-shielding ability which contains an infrared ray-absorbing compound or metal; a hard coat layer which scarcely suffers scratching; an anti-reflection layer having anti-reflective ability whose refractive index or film thickness has been adjusted; a non-glare layer or anti-glare layer having anti-glare properties such as dazzling-preventing properties; an antistatic layer; a stain-proof layer having the function of permitting easy removal of stains such as fingerprints; a UV ray-cutting layer; a layer having gas barrier properties; and a display panel breakage-preventing layer having the function of preventing scattering of glass pieces upon, for example, breakage of glass. These functional layers may be provided on the electro-conductive metal portion or on the opposite side of the electro-conductive metal portion with the transparent substrate being interposed therebetween.

Some of the functional transparent layers will further be described below.

The infrared ray-shielding layer, for example, a near infrared ray-absorbing layer is a layer containing a near infrared ray-absorbing dye such as a metal complex compound or a sputtered silver layer. Here, the sputtered silver layer can also cut a light of 1000 nm or longer of from near infrared rays, far infrared rays to electromagnetic wave when the layer is formed by alternately laminating a dielectric layer and a metal layer onto a substrate. The dielectric layer contains, as dielectric, a transparent metal oxide such as indium oxide or zinc oxide. As the metal to be contained in the metal layer, silver or silver-palladium alloy is popular. The above-described sputtered silver layer usually has a structure wherein about 3, 5, 7 or 11 layers are laminated, with the dielectric layer being the first layer.

In PDP, a blue light-emitting fluorescent body has the characteristic property of slightly emitting a red light in addition to the blue light, and hence it involves the problem that a portion to be displayed in a blue color is actually displayed in a violetish color. A layer having the function of absorbing a visible light of a specific wavelength region to thereby adjust color tone is a layer for correcting the color of emitted light for solving the problem and contains a dye capable of absorbing light of about 595 nm.

As a method for forming an anti-reflection layer having anti-reflective properties, there are a method of forming a single layer or multi-layers of an inorganic material such as a metal oxide, a fluoride, a silicide, a boride, a carbide, a nitride or a sulfide according to a vacuum deposition method, a sputtering method, an ion plating method or an ion beam assist method; and a method of forming, on the functional layer, a single layer or multi-layers of resins different in refractive index such as an acrylic resin or a fluorine-containing resin. Also, it is possible to stick on the film a film having been subjected to the anti-reflection treatment.

As a method for forming a non-glare layer or an anti-glare layer, there can be employed a method of coating on the surface an ink obtained from fine powders of silica, melamine or acryl. In this occasion, curing of the ink can be conducted by employing thermal curing or photo-curing. It is also possible to stick on the film a film having been subjected to the non-glare treatment or anti-glare treatment.

The light-transmittable electromagnetic wave shielding film of the invention has good electromagnetic wave shielding properties and good light-transmitting properties, and hence it is useful particularly as a film for use in display panel. The film of the invention for use in display panel can also be used as an optical filter for use in plasma display panel by providing, for example, the above-described functional transparent layer. These members can be applied to the display screen of CRT, PDP, liquid crystal or EL, a microwave oven, electronic devices, and printed wiring boards, with application to PDP being particularly useful.

The PDP of the invention has a high electromagnetic wave shielding ability, a high contrast and a high lightness, and can be prepared at a low cost.

### EXAMPLES

The invention will be described in more detail by reference to Examples. Additionally, materials, used amounts, proportions, contents of the treatment, the order of the treatments, and the like can properly be altered within the spirit of the invention. Therefore, the scope of the invention should not be construed in a limitative manner based on the specific examples to be described hereinafter.

### Example 1

A 100-μm thick transparent polyethylene naphthalate (PEN) film on which a gelatin undercoat layer was provided was used as a transparent substrate, ad the following silver paste was printed thereon according to the screen printing method.

Then, the film was heat-treated at 150° C. for 60 minutes. The thus-obtained mesh pattern was a silver lattice-like mesh of 20 μm in line width and 300 μm pitch.

Further, rust-inhibiting treatment was conducted using an aqueous solution containing the compound of the invention to be used in the invention (0.1 mol/L). Additionally, the rust-inhibiting treatment was conducted by dipping the film in the above-described aqueous solution for 3 minutes.

After the rust-inhibiting treatment, the film was washed with water and dried to obtain samples of the invention.

### (Preparation of the Silver Paste)

A silver nitrate solution was reduced according to the silver sol preparation method of Carey-Lea [See M. Carey Lea, Brit. J. Photog., vol. 24, p. 297 (1877) and vol. 27, p. 279 (1880)] to thereby prepare metal silver fine particles. Then, a solution of chloroauric acid was added thereto to prepare a silver-gold fine particles containing silver as a major component, followed by conducting ultrafiltration to remove by-produced salts. Observation by an electron microscope revealed that the particle size of the thus-obtained fine particles was about 10 nm.

The particles were mixed with an isopropyl alcohol-containing solvent and a binder to prepare the paste.

The content of silver based on the total mass of the metals constituting the printed pattern was 96% by mass.

### Comparative Example 1

A sample was prepared in the same manner as in Example 1 except for not conducting the rust-inhibiting treatment.

### <Evaluation Method>

### (Surface Resistance)

The surface resistivity was measured by means of a low resistivity meter Loresta manufactured by Mitsubishi Chemical.

The samples described in the following Table 1 were found to have a surface resistivity of 0.6 Ω/□.

### (Chemical Resistance (Salt Water Resistance))

Each of the above-described samples was dipped for 1 hour in an isotonic sodium chloride solution and, after drying, the color change degree of the metal portion in the dipped portion was visually evaluated. A sample showing color change was evaluated as x, and a sample showing no color change was evaluated as O.

### (Heat Resistance)

A heat resistance test was conducted at 100° C. for 1 week, and a sample undergoing an increase of surface resistance (decrease of electro-conductivity) of 1Ω/□ or more after the test was evaluated as x, and a sample undergoing an increase of surface resistance of less than 1Ω/□ was evaluated as O.

TABLE 1

| | | Color Change | | |
|---|---|---|---|---|
| | Rust-inhibiting | after Treatment | Heat | |
| | Treatment | with Salt Water | Resistance | Note |
| Example | compound 21 | ∘ | ∘ | present |
| 1-A | | | | invention |
| Example | compound 32 | ∘ | ∘ | present |
| 1-B | | | | invention |
| Example | compound 5-1 | ∘ | ∘ | present |
| 1-C | | | | invention |
| Comparative | None | x | x | comparative |
| Example 1 | | | | example |

As can be seen from Table 1, the samples of the invention shown in Example 1 were found to be excellent in chemical resistance such as salt water resistance and durability such as heat resistance. It was also confirmed that they had a sufficiently low surface resistivity and has good electromagnetic wave shielding ability.

In addition, surprisingly enough, improving effects were found with respect to pencil hardness (surface hardness) and tape-delaminating properties (adhesion properties).

### Example 2

A silver paste was prepared in the same manner as in Example 1, without employing chloroauric acid at the preparation of silver paste in Example 1, and the silver paste was printed in the same manner as in Example 1. Samples 2-A to 2-D containing the rust inhibitor of the present invention was prepared in the same manner as in Example 1, except for a treatment with an aqueous solution of Na₂PdCl₄.2H₂O (0.01 M) after a heating treatment. Also there were prepared a comparative sample 2 not utilizing the rust inhibitor. Also prepared was a comparative sample 3 without the treatments with Na₂PdCl₄.2H₂O and with the rust inhibitor.

### <Evaluation Method>

### (Color Change Resistance of Light-Transmitting Portion)

A standing test was executed for 1 week at 100° C., and a sample showing, after the test, a decrease in the transmittance at 410 nm of 8% or more was rated as X, from 4 to 8% as Δ, and 4% or less as O.

TABLE 2

| | | | Color | |
|---|---|---|---|---|
| | Rust | | change after | |
| | inhibiting | Color change | salt water | |
| No. | treatment | resistance | treatment | Note |
| Example 2-A | compound 21 | ∘ | ∘ | invention |
| Example 2-B | compound 32 | ∘ | ∘ | invention |
| Example 2-C | benzotriazole | Δ | ∘ | invention |
| Example 2-D | compound 5-1 | Δ | ∘ | invention |
| Comparative | none | x(significant | ∘ | comparative |
| Example 2 | | color change | | example |
| | | observed) | | |
| Comparative | none | ∘ | x | comparative |
| Example 3 | | | | example |
| | | | | (significant |
| | | | | silver |
| | | | | reflection) |

As will be apparent from the results above, among the samples treated with the aqueous solution of Na₂PdCl₄.2H₂O, those not treated with the rust inhibitor developed a drawback of a significant color change after standing, not in the metal portion but in the light-transmitting portion.

In contrast, the samples of the present invention, subjected to the rust inhibiting treatment on the metal, surprisingly showed little transmittance loss (color change) in the light-transmitting portion instead of the metal portion.

Also within the present invention, the compounds 21 and 32, which are the compounds of the formula (1), showed particularly excellent effects.

Also the samples of Examples, having a black printed pattern because of the palladium treatment, showed a significantly reduced reflection, in contrast to the sample not subjected to the palladium treatment and thus having a silver colored reflection. They are therefore advantageously usable as a light-transmittable electromagnetic wave shielding film for a display.

### Example 3

An emulsion containing 7.5 g of gelatin per 60 g of Ag in an aqueous medium and containing silver bromoiodide (I=2 mol %) grains of 0.05 μm in equivalent-sphere diameter was prepared. In this occasion, the Ag/gelatin volume ratio was adjusted to 1/1, and a low molecular mass gelatin of 20000 in average molecular mass was used as a gelatin species.

Also, to this emulsion was added K₃Rh₂Br₉ and K₂IrCl₆ to a concentration of 10⁻⁷ (mol/mol silver) to dope the silver bromide grains with Rh ion and Ir ion. Na₂PdCl₄ was added to this emulsion and, after conducting gold sulfur sensitization using chloroauric acid and sodium thiosulfate, the emulsion was coated on polyethylene terephthalate (PET) in a coated silver amount of 1 g/m². As PET, PET having previously been subjected to hydrophilicity-imparting treatment was used. The coated PET was dried and exposed through a lattice-like photomask (photomask having a lattice-like space of line/space=195 μm/5 μm; pitch: 200 μm) using a UV lamp, then developed at 25° C. for 45 seconds in the following developing solution, subjected to fixing treatment for 3 minutes using a fixing solution (SUPER FUJIFIX; manufactured by Fuji Photo Film Co., Ltd.), and rinsed with pure water.

### [Formulation of the Developing Solution]

The following compounds are contained per liter of the developing solution.

| | |
|---|---|
| Hydroquinone | 0.037 mol/L |
| N-Methylaminophenol | 0.016 mol/L |
| Sodium metaborate | 0.140 mol/L |
| Sodium hydroxide | 0.360 mol/L |
| Sodium bromide | 0.031 mol/L |
| Potassium metabisulfite | 0.187 mol/L |

Further, non-electrode plating was conducted at 45° C. using a plating solution (a non-electrode Cu plating solution of 12.5 in pH containing 0.06 mol/L of copper sulfate, 0.22 mol/L of formalin, 0.12 mol/L of triethanolamine, 100 ppm of polyethylene glycol, 50 ppm of yellow prussiate of potash and 20 ppm of α,α′-bipyridine). “ppm” is the same as “mg/L”. Further, color change-preventing treatment was conducted using an aqueous solution containing the compound of the invention (0.1 mol/L) described in Table 3. Additionally, this treatment was conducted by dipping in the aqueous solution for 3 minutes.

After the color change-preventing treatment, each sample was washed with water and dried to obtain samples of the invention.

### Comparative Example 4

A comparative sample was prepared in the same manner as in Example 3 except for not conducting the color change-preventing treatment.

### <Evaluating Method>

### (Surface Resistance)

The surface resistivity was measured by means of a low resistivity meter Loresta manufactured by Mitsubishi Chemical.

The samples described in the following Table 3 were found to have a surface resistivity of 0.3 Ω/□.

### (Moist Heat Resistance/Color Change in Electro-Conductive Metal Portion)

A moist heat resistance test was conducted for 2 days under the conditions of 80 C and 90% RH, and color change in the tested electro-conductive metal portion was visually evaluated. The color change was evaluated by observing the phenomenon that the metal copper color was changed to green to brown, thus moist heat resistance being judged.

A sample suffering color change was evaluated as x, and a sample not suffering color change was evaluated O.

### (Heat Resistance/Coloration in the Light-Transmitting Portion)

A heat resistance test was conducted at 100° C. for 1 week, and a sample undergoing a decrease of transmittance at 410 nm of 3% or more after the test was evaluated as x.

TABLE 3

| | Color change- | | | |
|---|---|---|---|---|
| | preventing | Moist Heat | Heat | |
| | Treatment | Resistance | Resistance | Note |
| Example | compound 22 | ∘ | ∘ | present |
| 3-A | | | | invention |
| Example | compound 32 | ∘ | ∘ | present |
| 3-B | | | | invention |
| Example | compound 5-1 | ∘ | ∘ | present |
| 3-C | | | | invention |
| Comparative | None | x | x | comparative |
| Example 4 | | | | example |

As can be seen from Table 3, the samples of the invention shown in Example 3 were found to difficultly suffer color change. In addition, surprisingly enough, it was found that an unexpected effect that the treatment in the invention prevents coloration of the light-transmitting portion which does not form the electro-conductive metal portion and therefore cannot be considered to rust.

### INDUSTRIAL APPLICABILITY

According to the invention, there can be provided a light-transmittable electromagnetic wave shielding film which has an excellent chemical resistance such as resistance against a salt water, an excellent heat resistance, an excellent resistance to moist heat, an excellent durability, less subjection to color change in time lapse and a high electromagnetic wave-shielding ability and which produces a small light scattering and has a high light transmittance; and a film for use in display panel, an optical filter for use in display panel and a plasma display panel for use in plasma display using the same.

Further, according to the invention, there can be provided a process for producing inexpensively on a large scale a light-transmittable electromagnetic wave shielding film which has an excellent durability and a high electromagnetic wave-shielding ability and which produces a small light scattering and has a high light transmittance. Also, the invention can provide a light-transmittable electromagnetic wave shielding film obtained by the production process, a film for use in display panel, an optical filter for use in display panel and a plasma display panel for use in plasma display having the film.

Further, surprisingly enough, the treatment with the organic mercapto compound employed in the invention serves to prevent coloration.

The entire disclosure of each and every foreign patent application from which the benefit of foreign priority has been claimed in the present application is incorporated herein by reference, as if fully set forth.

1. A light-transmittable electromagnetic wave shielding film comprising:
a transparent substrate;
a printed pattern containing silver as a major component; and
at least one rust inhibitor,
wherein the printed pattern containing silver as a major component comprises: an electro-conductive metal portion; and a light-transmitting portion, and
wherein the printed pattern contains silver in a content of 60% by mass or more based on a total mass of metals constituting the printed pattern.

2. The light-transmittable electromagnetic wave shielding film according to claim 1,
wherein the printed pattern contains silver in a content of 85% by mass or more.

3. The light-transmittable electromagnetic wave shielding film according to claim 1,
wherein the printed pattern contains silver and a noble metal other than silver.

4. The light-transmittable electromagnetic wave shielding film according to claim 1,
wherein the printed pattern contains silver and palladium, or silver and gold.

5. The light-transmittable electromagnetic wave shielding film according to claim 1,
wherein the at least one rust inhibitor is a 5-membered cyclic azole compound having an N—H structure.

6. The light-transmittable electromagnetic wave shielding film according to claim 1,
wherein the at least one rust inhibitor is an organic mercapto compound.

7. The light-transmittable electromagnetic wave shielding film according to claim 1,
wherein the at least one rust inhibitor is a combination of a 5-membered cyclic azole compound having an N—H structure and an organic mercapto compound.

8. The light-transmittable electromagnetic wave shielding film according to claim 6,
wherein the organic mercapto compound is a compound represented by formula (2):
Z-SM Formula (2)
wherein Z represents an alkyl group, an aromatic group or a hetero ring group substituted by at least one group selected from the group consisting of a hydroxyl group, —SO₃M² group, —COOM² group, an amino group and an ammonio group or by a substituent substituted by at least one member selected from the group consisting of a hydroxyl group, —SO₃M² group, —COOM² group, an amino group and an ammonio group, wherein M² represents a hydrogen atom, an alkali metal atom or an ammonium group; and
M represents a hydrogen atom, an alkali metal atom or an amidino group, which may optionally form a hydrohalogenic acid salt or a sulfonate.

9. The light-transmittable electromagnetic wave shielding film according to claim 6,
wherein the organic mercapto compound is at least one organic mercapto compound represented by formulae (1) and (3) to (5): 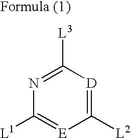
wherein -D= and -E= each independently represents —CH═ group, —C(R^{o})═ group or —N═ group;
R^{o} represents a substituent; and
L¹, L² and L³ each independently represents a hydrogen atom, a halogen atom or a substituent connected to the ring through a carbon atom, a nitrogen atom, an oxygen atom, a sulfur atom or a phosphorus atom, provided that at least one of L¹, L², L³ and R^{o} is —SM group, wherein M represents an alkali metal atom, a hydrogen atom or an ammonium group; 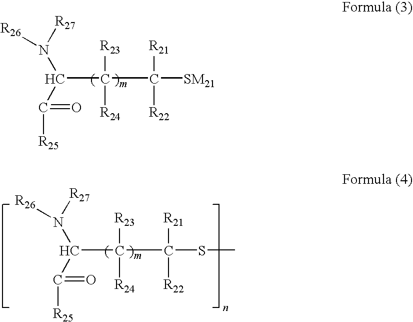
wherein R₂₁ and R₂₂ each independently represents a hydrogen atom or an alkyl group, provided that R₂₁ and R₂₂ do not represent a hydrogen atom at the same time and that the alkyl group may have a substituent;
R₂₃ and R₂₄ each independently represents a hydrogen atom or an alkyl group;
R₂₅ represents a hydroxyl group or a salt of the hydroxyl group, an amino group, an alkyl group or a phenyl group;
R₂₆ and R₂₇ each independently represents a hydrogen atom, an alkyl group, an acyl group or —COOM₂₂, provided that R₂₆ and R₂₇ do not represent a hydrogen atom at the same time;
M₂₁ represents a hydrogen atom, an alkali metal atom or an ammonium group;
M₂₂ represents a hydrogen atom, an alkyl group, an alkali metal atom, an aryl group or an aralkyl group;
m represents 0, 1 or 2; and
n represents 2; 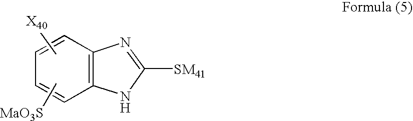
wherein X₄₀ represents a hydrogen atom, a hydroxyl group, a lower alkyl group, a lower alkoxy group, a halogen atom, a carboxyl group or a sulfo group;
M₄₁ and Ma each independently represents a hydrogen atom, an alkali metal atom or an ammonium group.

10. The light-transmittable electromagnetic wave shielding film according to claim 9,
wherein the organic mercapto compound is represented by formula (1).

11. The light-transmittable electromagnetic wave shielding film according to claim 1, which comprises the at least one rust inhibitor in an amount of from 0.001 to 0.04 g/m² with respect to the printed pattern.

12. The light-transmittable electromagnetic wave shielding film according to claim 1, which further comprises a functional transparent layer having one or more functions selected from among infrared ray-shielding properties, hard coat properties, anti-reflection properties, anti-glare properties, antistatic properties, stain-proof properties, UV ray-cutting properties, gas barrier properties and display panel damage-preventing properties.

13. A film for display panel, which comprises a light-transmittable electromagnetic wave shielding film according to claim 1.

14. (canceled)

15. A plasma display panel, which comprises a film for display panel according to claim 13 or an optical filter for plasma display panel comprising a film for display panel according to claim 13.

16. The process for producing a light-transmittable electromagnetic wave shielding film, which comprises:
forming an electro-conductive metal portion and a light-transmitting portion by printing, on a transparent substrate, fine particles containing silver as a major component in a content of 60% by mass or more based on a total mass of metals; and then
subjecting the electro-conductive metal portion and the light-transmitting portion to a treatment with at least one rust inhibitor.

17. A process for producing a light-transmittable electromagnetic wave shielding film according to claim 15, which further comprises:
subjecting the electro-conductive metal portion and the light-transmitting portion to a treatment with a liquid containing Pd ions between the forming of the electro-conductive metal portion and the light-transmitting portion and the treatment with at least one rust inhibitor.

18. A process for producing a light-transmittable electromagnetic wave shielding film, which comprises:
forming a metal silver portion and a light-transmitting portion by exposing a silver salt-containing layer provided on a transparent substrate and development-processing the exposed layer;
subjecting the metal silver portion to at least one of physical development and plating treatment to form an electro-conductive metal portion where an electro-conductive metal is supported on the metal silver portion; and
subjecting the electro-conductive metal portion to color change-preventing treatment with an organic mercapto compound.

19. The process for producing a light-transmittable electromagnetic wave shielding film according to claim 17,
wherein the organic mercapto compound is represented by formula (2):
Z-SM Formula (2)
wherein Z represents an alkyl group, an aromatic group or a hetero ring group substituted by at least one group selected from the group consisting of a hydroxyl group, —SO₃M² group, —COOM² group, an amino group and an ammonio group or by a substituent substituted by at least one member selected from the group consisting of a hydroxyl group, —SO₃M² group, —COOM² group, an amino group and an ammonio group, wherein M² represents a hydrogen atom, an alkali metal atom or an ammonium group; and
M represents a hydrogen atom, an alkali metal atom or an amidino group, which may optionally form a hydrohalogenic acid salt or a sulfonate.

20. The process for producing a light-transmittable electromagnetic wave shielding film according to claim 17,
wherein the organic mercapto compound is at least one organic mercapto compound represented by formulae (1) and (3) to (5): 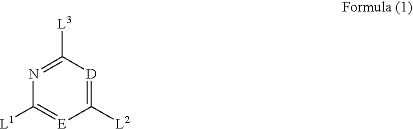
wherein -D= and -E= each independently represents —CH═ group, —C(R^{o})═ group or —N═ group;
R^{o} represents a substituent; and
L¹, L² and L³ each independently represents a hydrogen atom, a halogen atom or a substituent connected to the ring through a carbon atom, a nitrogen atom, an oxygen atom, a sulfur atom or a phosphorus atom, provided that at least one of L¹, L², L³ and R^{o} is —SM group, wherein M represents an alkali metal atom, a hydrogen atom or an ammonium group; 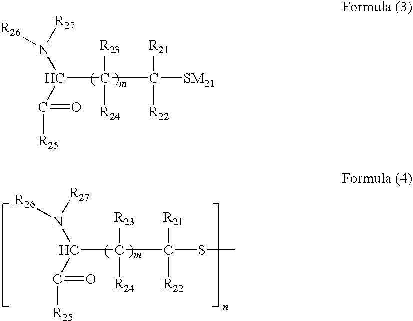
wherein R₂₁ and R₂₂ each independently represents a hydrogen atom or an alkyl group, provided that R₂₁ and R₂₂ do not represent a hydrogen atom at the same time and that the alkyl group may have a substituent;
R₂₃ and R₂₄ each independently represents a hydrogen atom or an alkyl group;
R₂₅ represents a hydroxyl group or a salt of the hydroxyl group, an amino group, an alkyl group or a phenyl group;
R₂₆ and R₂₇ each independently represents a hydrogen atom, an alkyl group, an acyl group or —COOM₂₂, provided that R₂₆ and R₂₇ do not represent a hydrogen atom at the same time;
M₂₁ represents a hydrogen atom, an alkali metal atom or an ammonium group;
M₂₂ represents a hydrogen atom, an alkyl group, an alkali metal atom, an aryl group or an aralkyl group;
m represents 0, 1 or 2; and
n represents 2; 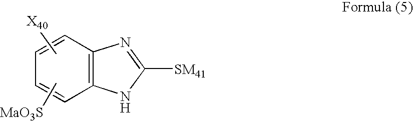
wherein X₄₀ represents a hydrogen atom, a hydroxyl group, a lower alkyl group, a lower alkoxy group, a halogen atom, a carboxyl group or a sulfo group;
M₄₁ and Ma each independently represents a hydrogen atom, an alkali metal atom or an ammonium group.

21. (canceled)

22. (canceled)

23. (canceled)

24. (canceled)

25. (canceled)
